(19) United States
(12) Patent Application Publication
(10) Pub. No.: US 2008/0106712 A1
(43) Pub. Date: May 8, 2008

(54) Liquid recovery member, substrate holding member, exposure apparatus and device manufacturing method

(75) Inventor: Hiroyuki Nagasaka, Kumagaya-shi (JP)

Correspondence Address: OLIFF & BERRIDGE, PLC, P.O. BOX 320850, ALEXANDRIA, VA, 22320-4850, US

(73) Assignee: NIKON CORPORATION, TOKYO (JP)

(21) Appl. No.: 11/806,041

(22) Filed: May 29, 2007

(30) Foreign Application Priority Data
May 29, 2006 (JP) 2006-148322

(51) Int. Cl. G03B 27/52; G03F 7/26

(52) U.S. Cl. 355/30; 430/311

(57) ABSTRACT

A substrate holding member includes: a first holding portion that detachably holds a substrate to be immersion exposed; and a second holding portion that detachably holds a liquid recovery member, the liquid recovery member including an opening portion in which a liquid having flowed out from an upper surface of the substrate held on the first holding portion flows.

### CROSS-REFERENCE TO RELATED APPLICATION

Priority is claimed on Japanese Patent Application No. 2006-148322, filed on May 29, 2006, the contents of which are incorporated herein by reference.

### BACKGROUND OF THE INVENTION

1. Field of the Invention

The present invention relates to a liquid recovery member, a substrate holding member, an exposure apparatus, and a device manufacturing method.

2. Description of Related Art

In exposure apparatuses for use in a photolithography process, there are proposed liquid immersion exposure apparatuses as disclosed in PCT International Publication No. WO 99/49504 and PCT International Publication No. WO 2004/102646, in which a substrate is exposed via a liquid.

In a liquid immersion exposure apparatus, when a liquid on a substrate is recovered, there is a possibility that favorable recovery of the liquid may be difficult according to the type (property) of the liquid and/or the materiality of the surface of the substrate.

A purpose of some aspects of the invention is to provide a liquid recovery member that can favorably recover a liquid. Another purpose is to provide a substrate holding member that can favorably recover the liquid and favorably hold a substrate. Still another purpose is to provide an exposure apparatus that can favorably recover the liquid and favorably expose the substrate, and a device manufacturing method.

### SUMMARY OF THE INVENTION

According to a first aspect of the present invention, there is provided a liquid recovery member that is detachably held by a movable member capable of moving with respect to an optical path of an exposure light to be irradiated onto a substrate via a liquid and that includes an opening portion in which a liquid having flowed out from an upper surface of the substrate flows.

According to the first aspect of the present invention, a liquid can be favorably recovered.

According to a second aspect of the present invention, there is provided a substrate holding member for holding a substrate to be immersion exposed, including: a first holding portion that detachably holds a substrate; and a second holding portion that detachably holds a liquid recovery member that recovers a liquid having flowed out from an upper surface of the substrate that is held by the first holding portion.

According to the second aspect of the present invention, a liquid can be favorably recovered and a substrate can be favorably held.

According to a third aspect of the present invention, there is provided an exposure apparatus, including the substrate holding member of the above-mentioned aspect, in which a liquid immersion exposure for a substrate held by the substrate holding member is performed by irradiating an exposure light onto the substrate via a liquid.

According to the third aspect of the present invention, a liquid can be favorably recovered and a substrate can be favorably exposed.

According to a fourth aspect of the present invention, there is provided a device manufacturing method, including: exposing a substrate by using the exposure apparatus of the above-mentioned aspect and developing the substrate that has been exposed.

According to the fourth aspect of the present invention, a device can be manufactured using an exposure apparatus that can favorably expose a substrate.

According to the present invention, a liquid can be favorably recovered. Furthermore, a substrate can be favorably exposed, and a device with desired performance can be manufactured.

### BRIEF DESCRIPTION OF THE DRAWINGS

FIG. 1 is a side view showing a schematic configuration of an exposure apparatus according to a first embodiment.

FIG. 2 is a plan view showing a schematic configuration of the exposure apparatus according to the first embodiment.

FIG. 3 is a side cross-sectional view showing a vicinity of a substrate stage according to the first embodiment.

FIG. 4 is a plan view of the substrate stage according to the first embodiment, seen from above.

FIG. 5 is an enlarged view of part of FIG. 3.

FIG. 6 is a partly cutaway perspective view showing a first transfer system according to the first embodiment transferring a liquid recovery member.

FIG. 7A is a schematic diagram showing an example of an operation of the first transfer system according to the first embodiment.

FIG. 7B is a schematic diagram showing an example of an operation of the first transfer system according to the first embodiment.

FIG. 7C is a schematic diagram showing an example of an operation of the first transfer system according to the first embodiment.

FIG. 8 is a schematic diagram for explaining an example of an operation of the exposure apparatus according to the first embodiment.

FIG. 9 is a schematic diagram for explaining an example of an operation of the exposure apparatus according to the first embodiment.

FIG. 10 is a schematic diagram for explaining an example of an operation of the exposure apparatus according to the first embodiment.

FIG. 11 is a schematic diagram for explaining an example of an operation of the exposure apparatus according to the first embodiment.

FIG. 12 is a schematic diagram for explaining an example of an operation of the exposure apparatus according to the first embodiment.

FIG. 13 is a schematic diagram for explaining an example of an operation of the exposure apparatus according to the first embodiment.

FIG. 14 is a schematic diagram for explaining an example of an operation of the exposure apparatus according to the first embodiment.

FIG. 15 is a schematic diagram for explaining an example of an operation of the exposure apparatus according to the first embodiment.

FIG. 16 is a schematic diagram for explaining an example of an operation of the exposure apparatus according to the first embodiment.

FIG. 17 is a schematic diagram for explaining an example of an operation of the exposure apparatus according to the first embodiment.

FIG. 18 is an enlarged view of a part of a side cross-sectional view showing a vicinity of a substrate stage according to a second embodiment.

FIG. 19 is an enlarged view of a part of a side cross-sectional view showing a vicinity of a substrate stage according to a third embodiment.

FIG. 20 is a side cross-sectional view showing a vicinity of a substrate stage according to a fourth embodiment.

FIG. 21 is a partly cutaway view of a perspective view showing that a first transfer system according to the fourth embodiment is transferring a liquid recovery member.

FIG. 22 is a side cross-sectional view showing a vicinity of a substrate stage according to a fifth embodiment.

FIG. 23 schematically shows an exposure apparatus according to a sixth embodiment.

FIG. 24 is a flow chart showing an example of manufacturing steps for a micro device.

### DETAILED DESCRIPTION OF THE INVENTION

Hereunder is a description of embodiments of the present invention with reference to the drawings. However, the present invention is not limited to this description. In the following description, an XYZ orthogonal co-ordinate system is established, and the positional relationship of respective members is described with reference to this XYZ orthogonal co-ordinate system. A predetermined direction within a horizontal plane is made the X axis direction, a direction orthogonal to the X axis direction in the horizontal plane is made the Y axis direction, and a direction orthogonal to both the X axis direction and the Y axis direction (that is, a perpendicular direction) is made the Z axis direction. Furthermore, rotation (tilting) directions about the X axis, the Y axis and the Z axis, are made the θX, the θY, and the θZ directions respectively.

### First Embodiment

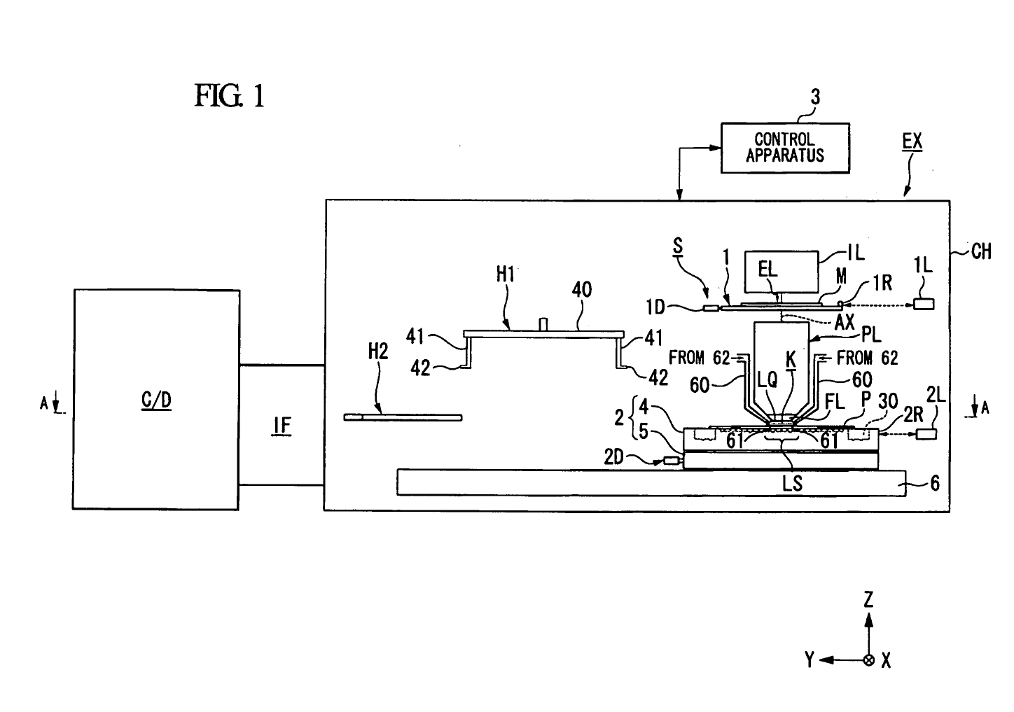

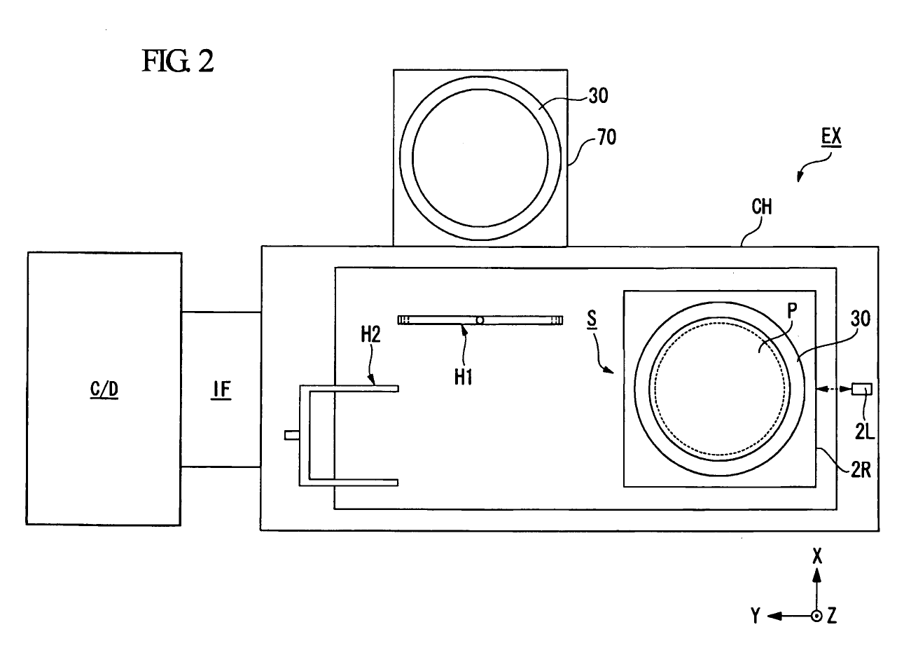

A first embodiment will be explained. FIG. 1 is a side view showing a schematic configuration of an exposure apparatus EX according to a first embodiment. FIG. 2 is a plan view showing a schematic configuration of the exposure apparatus EX according to the first embodiment, which corresponds to a cross-sectional view taken along the A-A arrow of FIG. 1.

In FIG. 1 and FIG. 2, the exposure apparatus EX includes: an exposure apparatus body S for irradiating an exposure light EL onto a substrate P to exposure process the substrate P; and a control apparatus 3 for controlling operation of the whole exposure apparatus EX.

The exposure apparatus body S includes: a mask stage 1 capable of holding and moving a mask M with a pattern; a substrate stage 2 capable of holding and moving the substrate P onto which the exposure light EL is irradiated; an illumination system IL for illuminating the mask M held on the mask stage 1 with the exposure light EL; and a projection optical system PL for projecting an image of a pattern of the mask M illuminated by the exposure light EL onto the substrate P.

The substrate P here includes one a sensitive material (photoresist) or a film such as a protection film is spread on a substrate of a semiconductor wafer or the like. The mask M includes a reticle formed with a device pattern which is reduction size projected onto the substrate P. In the present embodiment, a transmission mask is used as the mask. However, a reflecting mask may be used.

The exposure apparatus EX of the present embodiment is a liquid immersion exposure apparatus to which an immersion method is applied for substantially shortening the exposure length and improving the resolution, and also substantially expanding the depth of focus. The exposure apparatus EX forms an immersion space LS so as to fill with a liquid LQ an optical path space K of the exposure light EL between an optical element FL of the projection optical system PL and the substrate P, and exposes the substrate P via the liquid LQ in the immersion space LS. The immersion space LS is a space, filled with the liquid LQ, between the substrate P and an object facing the substrate P (for example, the optical element FL).

The exposure apparatus EX includes a liquid supply member 60 that supplies the liquid LQ for forming the immersion space LS between the projection optical system PL and the substrate P. In the present embodiment, the liquid supply member 60 is arranged above the substrate P held on the substrate stage 2, and is capable of supplying the liquid LQ onto the substrate P from above the substrate P. The liquid supply member 60 is arranged in the vicinity of the optical path space K of the exposure light EL. It includes a liquid supply port 61 capable of facing an upper surface of the substrate P held on the substrate stage 2, and supplies the liquid LQ onto the substrate P via the liquid supply port 61 so as to fill the optical path space K of the exposure light EL between the projection optical system PL and the substrate P.

The optical element FL, which is closest to the image plane of the projection optical system PL among a plurality of optical elements of the projection optical system PL, is capable of holding the liquid LQ between itself and the upper surface of the substrate P arranged on the image plane side of the projection optical system PL. The liquid LQ supplied from the liquid supply member 60 is held between a bottom surface of the optical element FL and the upper surface of the substrate P that faces the bottom surface of the optical element FL, thus forming at least a part of the immersion space LS.

The exposure apparatus EX performs liquid immersion exposure for the substrate P by: forming the immersion space LS so as to fill the optical path space K of the exposure light EL with the liquid LQ by using the liquid supply member 60, at least while projecting the image of the pattern of the mask M onto the substrate P; and irradiating the exposure light EL having passed through the mask M onto the substrate P held on the substrate stage 2 via the projection optical system PL and the liquid LQ in the immersion space LS to project the image of the pattern of the mask M onto the substrate P.

In the present embodiment, a liquid recovery member 30 for recovering the liquid LQ having flowed out from the upper surface of the substrate P held on the substrate stage 2 is arranged at a predetermined position. The liquid recovery member 30 is detachably held on the substrate stage 2. In the present embodiment, the liquid recovery member 30 is an annular member, which is held on the substrate stage 2 so as to surround the substrate P. The substrate stage 2 includes a holder member 4 that detachably holds the substrate P. In the present embodiment, the liquid recovery member 30 is detachably held in the holder member 4.

The exposure apparatus EX includes a first transfer system H1 that is capable of transferring the liquid recovery member 30. The first transfer system H1 is capable of performing at least either one of the carry-in operation of the liquid recovery member 30 to the substrate stage 2 (the holder member 4) or the carry-out operation of the liquid recovery member 30 from the substrate stage 2 (the holder member 4).

Furthermore, the exposure apparatus EX includes a container apparatus 70 that is capable of containing the liquid recovery member 30. The container apparatus 70 is arranged at a position spaced away from the substrate stage 2. The exposure apparatus EX includes a chamber apparatus CH that contains at least an illumination system IL, a mask stage 1, a projection optical system PL, and a substrate stage 2. In the present embodiment, the container apparatus 70 is connected to the chamber apparatus CH. Note that, in the present embodiment, the container apparatus 70 is arranged outside the chamber apparatus CH. However, it may be arranged inside the chamber apparatus CH.

The first transfer system H1 is capable of performing at least either one of the carry-out operation of the liquid recovery member 30 from the container apparatus 70 or the carry-in operation of the liquid recovery member 30 to the container apparatus 70. The first transfer system H1 is capable of transferring the liquid recovery member 30 between the container apparatus 70 and the substrate stage 2 (the holder member 4).

Furthermore, the exposure apparatus EX includes a second transfer system H2 that is capable of transferring the substrate P. In the present embodiment, to the exposure apparatus EX, there is connected, via an interface IF, a coater/developer apparatus C/D including a coating apparatus (not shown in the figure) for forming a thin film on the substrate P and a developer apparatus (not shown in the figure) for developing the post-exposure-processed substrate P. The second transfer system H2 is capable of transferring the pre-exposure-processed substrate P, which has been carried in from the coater/developer apparatus C/D (the coating apparatus) via the interface IF, to a predetermined position in the exposure apparatus EX (in the chamber apparatus CH). Furthermore, the second transfer system H2 is capable of transferring the post-exposure-processed substrate P to the vicinity of a connection portion with the interface IF. The post-exposure-processed substrate P is then transferred to the coater/developer apparatus C/D via the interface IF. In the present embodiment, the second transfer system H2 transfers only the substrate P, and is capable of transferring the substrate P to/from the first transfer system H1. In the present embodiment, the thin film formed on the substrate P by the coating apparatus (not shown in the figure) includes a film made of a photosensitive material (a so-called resist) formed on a base material of a semiconductor wafer or the like, a protection film called a topcoat film that covers the film made of the photosensitive material, and the like.

First, the illumination system IL of the exposure apparatus body S will be described. The illumination system IL illuminates a predetermined illumination region on the mask M with the exposure light EL of a uniform luminance distribution. For the exposure light EL radiated from the illumination system IL, for example emission lines (g-rays, h-rays, i-rays), radiated for example from a mercury lamp, deep ultraviolet beams (DUV light beams) such as the KrF excimer laser beam (wavelength: 248 nm), and vacuum ultraviolet light beams (VUV light beams) such as the ArF excimer laser beam (wavelength: 193 nm) and the F₂ laser beam (wavelength: 157 nm), may be used. In the present embodiment, the ArF excimer laser beam is used.

Next is a description of the mask stage 1. The mask stage 1 is movable by drive of a mask stage driving unit 1D which includes an actuator such as a linear motor, in the X axis, the Y axis, and the θZ directions while holding the mask M. Position information of the mask stage 1 (and consequently the mask M) is measured with a laser interferometer 1L. The laser interferometer 1L uses a measurement mirror 1R which is provided on the mask stage 1 to measure the position information of the mask stage 1. The control apparatus 3 controls the mask stage driving unit 1D based on the measured results of the laser interferometer 1L, and controls the position of the mask M which is held on the mask stage 1.

Next is a description of the projection optical system PL. The projection optical system PL is one which projects an image of a pattern of the mask M onto the substrate P at a predetermined projection magnification, and has a plurality of optical elements, and these optical elements are held in a lens barrel. The projection optical system PL of the present embodiment is a reduction system with a projection magnification of for example ¼, ⅕, ⅛ or the like, and forms a reduced image of the mask pattern on the projection region conjugate with the aforementioned illumination region. The projection optical system PL may be a reduction system, an equal system or a magnification system. Furthermore, the projection optical system PL may include any one of: a dioptric system which does not include a reflection optical element, a catoptric system which does not include a refractive optical element, or a cata-dioptric system which includes a reflection optical system and a refractive optical system. Moreover, the projection optical system PL may form either an inverted image or an erect image.

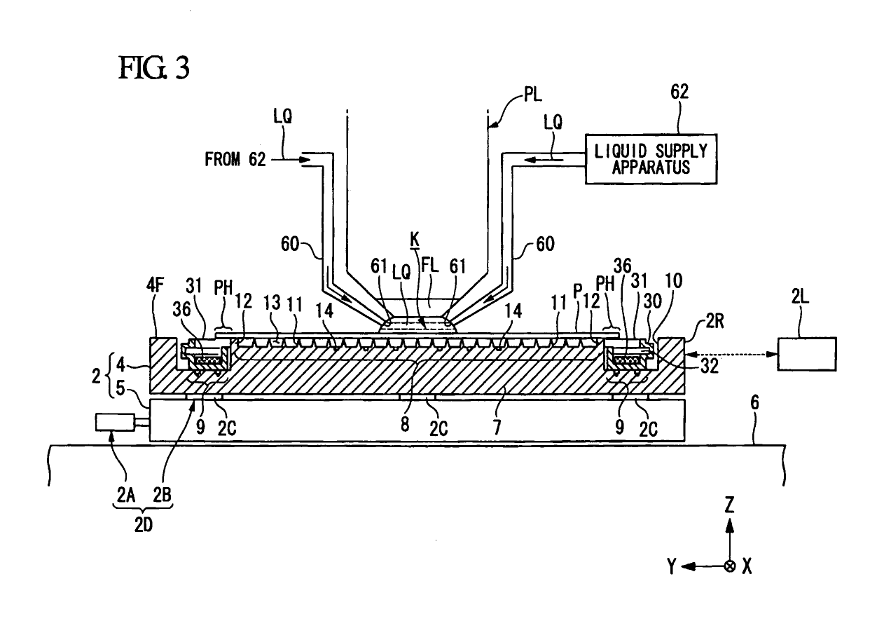

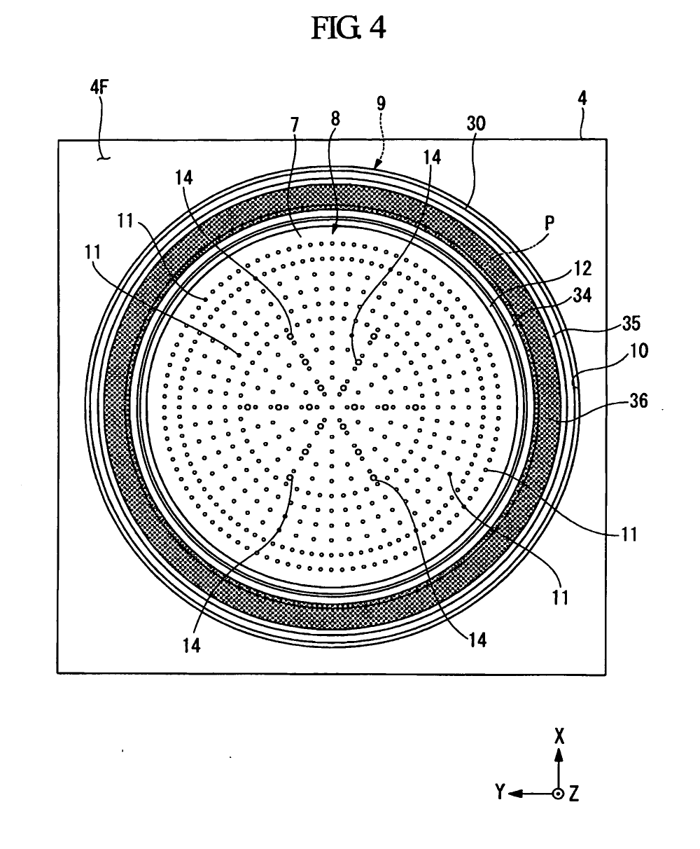

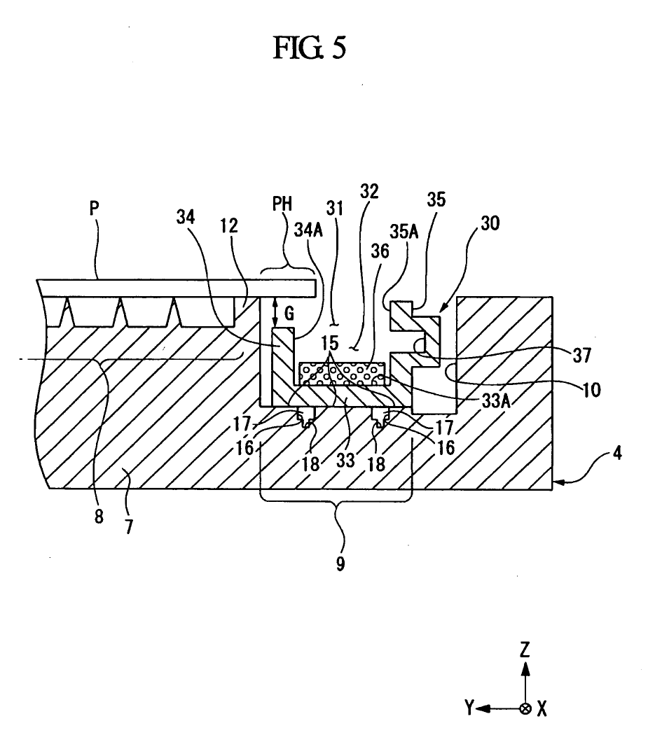

Next is a description of the substrate stage 2 with reference to FIG. 3, FIG. 4, and FIG. 5. FIG. 3 is a side cross-sectional view showing a vicinity of the substrate stage 2. FIG. 4 is a plan view of the substrate stage 2, seen from above. FIG. 5 is an enlarged view of a part of FIG. 3. FIG. 3 shows that the substrate P is present on the substrate stage 2, while FIG. 4 shows that the substrate P is not present on the substrate stage 2. In FIG. 4, the edge of the substrate P is denoted with a double-dot chain line.

The substrate stage 2 including the holder member 4 is movable with respect to an optical path of the exposure light EL. In the present embodiment, an optical axis AX of the projection optical system PL through which the exposure light EL passes is substantially parallel with the Z axis. The substrate stage 2 includes a stage body 5 and the holder member 4 that is mounted on the stage body 5 for holding the substrate P. The stage body 5 is contactlessly supported by an air bearing with respect to an upper surface (a guide surface) of a base member 6. The upper surface of the base member 6 is substantially parallel with the XY plane. The substrate stage 2 including the stage body 5 and the holder member 4 is movable on the base member 6 in the X and Y directions.

The substrate stage 2 is movable on the base member 6, while holding the substrate P on the holder member 4, by means of driving a substrate stage driving unit 2D which includes an actuator such as a linear motor. The substrate stage driving unit 2D includes: a first drive system 2A that is capable of moving the holder member 4 mounted on the stage body 5 in the X axis, Y axis and θZ directions by moving the stage body 5 on the base member 6 in the X axis, Y axis and θZ directions; and a second drive system 2B that is capable of moving the holder member 4 in the Z axis, θX, and θY directions with respect to the stage body 5.

The first drive system 2A includes an actuator such as a linear motor and is capable of driving the stage body 5 contactlessly supported above the base member 6 in the X axis, Y axis, and θZ directions. The second drive system 2B includes: a plurality of actuators 2C, such as voice coil motors, that are interposed between the stage body 5 and the holder member 4; and a measuring apparatus (encoder or the like) (not shown in the figure) that measures the drive amount of the respective actuators 2C. The holder member 4 is supported above the stage body 5 by at least three actuators 2C. Each of the actuators 2C is independently capable of driving the holder member 4 in the Z axis direction with respect to the stage body 5. The control apparatus 3, by adjusting the respective drive amount of the plurality of (at least three) actuators 2C, drives the holder member 4 in the Z axis, θX, and θY directions with respect to the stage body 5.

Thus, the substrate stage driving unit 2D including the first drive system 2A and the second drive system 2B is capable of moving the holder member 4 of the substrate stage 2 in a direction of six degrees of freedom of: the X axis, the Y axis, the Z axis, the θX, the θY and the θZ directions. The control apparatus 3, by controlling the substrate stage driving unit 2D, is capable of controlling the position of the upper surface (the surface) of the substrate P held on the holder member 4 in relation to the direction of six degrees of freedom of: the X axis, the Y axis, the Z axis, the θX, the θY and the θZ directions.

Position information of the holder member 4 of the substrate stage 2 (and consequently the substrate P) is measured by a laser interferometer 2L. The laser interferometer 2L uses a reflection surface 2R which is provided on the holder member 4 to measure the position information of the holder member 4 in relation to the X axis, the Y axis, and the θZ directions. Furthermore, surface position information of the upper surface (the surface) of the substrate P held on the holder member 4 (position information related to the Z axis, the θX, and the θY directions) is detected by a focus leveling detection system (not shown in the figure). The control apparatus drives the substrate stage driving unit 2D based on the measurement results of the laser interferometer 2L, and the detection results of the focus leveling detection system, to control the position of the substrate P which is held on the holder member 4.

The focus leveling detection system is one which detects inclination information (rotation angle) for the θX and the θY directions of the substrate by measuring position information for a plurality of measurement points for the Z axis direction of the substrate. Moreover, when for example the laser interferometer is capable of measuring the position information for the Z axis, the θX, and the θY directions of the substrate, then it is possible to omit the focus leveling detection system for measuring the position information for the Z axis direction during the exposure operation of the substrate, and position control of the substrate P in relation to the Z axis, the θX, and the θY directions can be performed using the measurement results of the laser interferometer, at least during the exposure operation.

The holder member 4 includes: a base material 7; a first holding portion 8 provided on the base material 7 for detachably holding the substrate P; and a second holding portion 9 provided on the base material 7 for detachably holding the liquid recovery member 30. The first holding portion 8 is provided in a central region of the upper surface of the base material 7, the region being capable of facing the bottom surface of the substrate P. The second holding portion 9 is arranged outside the first holding portion 8. In the base material 7, there is formed a recess portion 10 that is formed so as to surround the first holding portion 8. The second holding portion 9 is provided inside the recess portion 10. The recess portion 10 is formed in an annular shape within the XY plane.

The first holding portion 8 is formed on the base material 7 and includes: first support members 11 formed on the base material 7 for supporting the bottom surface of the substrate P; and a peripheral wall member 12 that is formed on the base material 7 and is provided so as to surround the first support members 11. The peripheral wall member 12 is formed in an annular shape within the XY plane so as to have substantially the same shape as the outline of the substrate P.

The first support members 11 are pin-like protrusion members formed on the upper surface of the base material 7. They are respectively arranged at a plurality of predetermined positions on the upper surface of the base material 7 inside the peripheral wall member 12. In the present embodiment, the first support members 11 are provided substantially uniformly on the upper surface of the base material 7.

The bottom surface of the substrate P is supported by upper surfaces of the first support members 11. The upper surface of the first support member 11 forms a support surface for supporting the bottom surface of the substrate P.

An upper surface of the peripheral wall member 12 is provided so as to face a peripheral region (an edge region) of the substrate P. In the present embodiment, the upper surfaces of the first support members 11 and the upper surface of the peripheral wall member 12 are arranged at substantially the same position (height) with respect to the Z axis direction. Furthermore, in the present embodiment, an outer diameter of the peripheral wall member 12 is formed slightly shorter than an outer diameter of the substrate P. In other words, when the substrate P is held on the first holding portion 8, the peripheral wall member 12 is positioned inside the edge of the substrate P (on the center side of the substrate P). That is, the peripheral region of the substrate P overhangs outside the peripheral wall member 12 by a predetermined amount.

In the following description, a part of the region of the substrate P that outwardly overhangs from the peripheral wall member 12 is appropriately referred to as an overhang region PH.

On the bottom surface side of the substrate P held on the first holding portion 8, there is formed a first space 13 surrounded by the bottom surface of the substrate P, the peripheral wall member 12, and the base material 7. The first holding portion 8 holds the substrate P so that the center of the first space 13 and the center of the bottom surface of the substrate P are substantially aligned.

On the base material 7 of the first space 13, there are provided a plurality of first suction ports 14 for suctioning fluid (mainly gas) for applying negative pressure to the first space 13. In the first space 13, the first suction ports 14 are respectively formed at a plurality of predetermined positions other than where the first support members 11 are provided.

Each of the first suction ports 14 is connected with a suction apparatus (not shown in the figure) including a vacuum system and the like via a passage, and is also connected with the first space 13. The control apparatus 3 is capable of suctioning the fluid (mainly gas) in the first space 13 by driving the suction apparatus connected with the first suction ports 14. The control apparatus 3 drives the suction apparatus connected with the first suction ports 14, which suction the fluid (mainly gas) in the first space 13 surrounded by the bottom surface of the substrate P, the peripheral wall member 12, and the base material 7 to apply negative pressure to the first space 13, thus holding via suction the bottom surface of the substrate P by means of the first supporting members 11. Furthermore, the substrate P can be detached from the first holding portion 8 by stopping the suction operation by the suction apparatus connected with the first suction ports 14. In this manner, in the present embodiment, by performing the suction operation by use of the first suction ports 14 and stopping the suction operation, the substrate P can be attached to/detached from the first holding portion 8. In the present embodiment, the first holding portion 8 includes a so-called pin chuck structure.

The second holding portion 9 is formed in the base material 7 and includes a plurality of second supporting members 15 for supporting the liquid recovery member 30. The second supporting members 15 are provided inside the recess portion 10 formed in the base material 7 so as to surround the first holding portion 8. The second supporting members 15 are arranged so that the upper surfaces thereof face the bottom surface of the liquid recovery member 30. The second supporting members 15 are formed in an annular shape within the XY plane in accordance with the shape of the liquid recovery member 30, and hence they are provided in concentric circular shapes.

The liquid recovery member 30 is supported by the upper surfaces of the second supporting members 15. The upper surface of the second supporting member 15 forms a supporting surface for supporting the bottom surface of the liquid recovery member 30.

In the present embodiment, the upper surfaces of the second supporting members 15 are arranged at substantially the same position (height) with respect to the Z axis direction. That is, the upper surfaces of the second supporting members 15 are arranged on substantially the same plane, and hence they are flush with each other.

Between the adjacent second supporting members 15, there is formed an annular-shaped groove 16 within the XY plane. On the bottom surface side of the liquid recovery member 30 held on the second holding portion 9, there are formed second spaces 17 surrounded by the bottom surface of the liquid recovery member 30, the second supporting members 15, and the base material 7.

On the base material 7 that is in contact with the second spaces 17, a plurality of second suction ports 18 are provided for suctioning fluid (mainly gas) to apply negative pressure to the second spaces 17. In the second space 17, the second suction port 18 is formed at each of a plurality of predetermined positions inside the grooves 16.

Each of the second suction ports 18 is connected with a suction apparatus including a vacuum system (not shown in the figure) via a passage, and is also connected with the second space 17. The control apparatus 3 is capable of suctioning the fluid (mainly gas) in the second spaces 17 by driving the suction apparatus connected with the second suction ports 18. The control apparatus 3 drives the suction apparatus connected with the second suction ports 18, which suction the fluid (mainly gas) in the second spaces 17 surrounded by the bottom surface of the liquid recovery member 30, the second supporting members 15, and the base material 7 to apply negative pressure to the second spaces 17, thus holding via suction the bottom surface of the liquid recovery member 30 by means of the second supporting members 15. Furthermore, the liquid recovery member 30 can be detached from the second holding portion 9 by stopping the suction operation by the suction apparatus connected with the second suction ports 18. In this manner, in the present embodiment, by performing the suction operation by use of the second suction ports 18 and stopping the suction operation, the liquid recovery member 30 can be attached to/detached from the second holding portion 9.

Note that the second holding portion 9 may hold the liquid recovery member 30 by use of the pin chuck structure, similarly to the case with the first holding portion 8. Furthermore, although the first holding portion 8 and the second holding portion 9 are described as a vacuum attraction type in the present embodiment, the type is not limited thereto. For example, an electrostatic attraction type may be adopted.

Next is a description of the liquid recovery member 30 with reference to FIG. 3, FIG. 4, and FIG. 5. The liquid recovery member 30 is detachably held in the second holding portion 9 of the holder member 4 that is movable with respect to the optical path of the exposure light EL, and recovers the liquid LQ having flowed out from the upper surface of the substrate P. The liquid recovery member 30 is an annular member within the XY plane. At least a part thereof is capable of being arranged inside the recess portion 10 formed in the base material 7. It is held in the second holding portion 9 so as to surround the substrate P.

The liquid recovery member 30 has: an opening portion 31 that is arranged so that the liquid from the upper surface of the substrate P flows therein; and a recess-shaped liquid holding portion 32 that is formed below the opening portion 31 and is formed so as to be capable of holding a predetermined amount of the liquid LQ having flowed in from the opening portion 31.

The liquid recovery member 30 includes: a bottom plate 33 formed in an annular shape within the XY plane; a first side plate 34 connected with an inner edge of the bottom plate 33; and a second side plate 35 connected with an outer edge of the bottom plate 33. The bottom plate 33, the first side plate 34, and the second side plate 35 are each formed in an annular shape within the XY plane. The bottom plate 33 has a bottom surface 33A that faces upward (in the +Z direction). The first side plate 34 has a first side surface 34A. The second side plate 35 has a second side surface 35A. The first side surface 34A and the second side surface 35A face each other substantially in parallel, with a predetermined gap therebetween. The first side surface 34A and the second side surface 35A are substantially perpendicular to the XY plane. The opening portion 31 is formed between an upper end of the first side surface 34A and an upper end of the second side surface 35A. The liquid holding portion 32 is formed by the opening portion 31, the bottom surface 33A, the first side surface 34A, and the second side surface 35A.

In the present embodiment, the liquid recovery member 30 is formed of a fluorine-based resin such as polytetrafluoroethylene (Teflon®). The liquid recovery member 30 may be formed of metal or the like, and the surface thereof may be coated with a fluorine-based resin.

In the present embodiment, the holder member 4 holds the liquid recovery member 30 in the second holding portion 9 so that the opening portion 31 faces upward. At least a part of the liquid recovery member 30 held in the second holding portion 9 of the holder member 4 is arranged at a position lower than the upper surface of the substrate P held on the first holding portion 8. Furthermore, at least a part of the opening portion 31 of the liquid recovery member 30 held in the second holding portion 9 of the holder member 4 is arranged at a position lower than the upper surface of the substrate P held on the first holding portion 8.

In the present embodiment, the holder member 4 holds the liquid recovery member 30 in the second holding portion 9 so that at least a part of the liquid recovery member 30 faces the bottom surface of the substrate P held on the first holding portion 8. As described above, the first holding portion 8 holds the substrate P so that the peripheral region of the bottom surface of the substrate P outwardly overhangs from the peripheral wall member 12. The second holding portion 9 holds the liquid recovery member 30 in the second holding portion 9 so that the overhang region PH of the bottom surface of the substrate P faces at least a part of the liquid recovery member 30.

In the present embodiment, the holder member 4 holds the liquid recovery member 30 in the second holding portion 9 so that the upper surface of the first side plate 34 of the liquid recovery member 30 faces the overhang region PH of the bottom surface of the substrate P held on the first holding portion 8. In the present embodiment, an outer diameter of the first side plate 34 is formed slightly shorter than the outer diameter of the substrate P, and hence the upper surface of the first side plate 34 is capable of facing the peripheral region of the bottom surface of the substrate P.

Furthermore, the holder member 4 holds the liquid recovery member 30 in the second holding portion 9 so that the upper surface of the second side plate 35 of the liquid recovery member 30 does not face the overhang region PH of the bottom surface of the substrate P held on the first holding portion 8. The opening portion 31 of the liquid recovery member 30 is formed between the upper end of the first side surface 34A of the first side plate 34 and the upper end of the second side surface 35A of the second side plate 35. The holder member 4 holds the liquid recovery member 30 in the second holding portion 9 so that a part of the opening portion 31 faces the overhang region PH of the bottom surface of the substrate P held on the first holding portion 8.

The liquid recovery member 30 is an annular member within the XY plane. The holder member 4 holds the liquid recovery member 30 in the second holding portion 9 so as to surround the substrate P. The opening portion 31 of the liquid recovery member 30 is also formed in an annular shape within the XY plane. The holder member 4 holds the liquid recovery member 30 in the second holding portion 9 so that the opening portion 31 of the liquid recovery member 30 surrounds the substrate P held on the first holding portion 8.

Thus, in the present embodiment, the liquid recovery member 30 is held in the second holding portion 9 of the holder member 4 so that the opening portion 31 of the liquid recovery member 30 faces upward (in the +Z direction) and so that the upper surface of the first side plate 34 faces the bottom surface of the substrate P held on the first holding portion 8 to allow a part of the opening portion 31 to face the bottom surface of the substrate P. Furthermore, the liquid recovery member 30 is held in the second holding portion 9 of the holder member 4 so that the opening portion 31 of the liquid recovery member 30 surrounds the substrate P held on the first holding portion 8.

In the present embodiment, at least the upper surface of the first side plate 34 and the opening portion 31 of the liquid recovery member 30 have a shape corresponding to the outline of the substrate P. As a result, it is possible for the entirety of the peripheral region of the bottom surface of the substrate P held on the first holding portion 8 to face the upper surface of the first side plate 34 of the liquid recovery member 30 held in the second holding portion 9 and a part of the opening portion 31 along the first side plate 34.

Furthermore, in the present embodiment, the substrate P held on the first holding portion 8 is spaced away from the liquid recovery member 30 held in the second holding portion 9. As shown in FIG. 5, a predetermined gap G is formed between the overhang region PH of the bottom surface of the substrate P held on the first holding portion 8 and the upper surface of the first side plate 34, of the liquid recovery member 30, that is arranged so as to face the overhang region PH.

The liquid recovery member 30 is capable of support the substrate P by means of the upper surface of the first side plate 34. As described above, the outer diameter of the first side plate 34 is formed slightly shorter than the outer diameter of the substrate P, and hence the upper surface of the first side plate 34 is capable of facing the peripheral region of the bottom surface of the substrate P. For example, by moving the liquid recovery member 30 in the +Z direction after stopping the suction of the substrate P on the first holding portion 8 and the suction of the liquid recovery member 30 in the second holding portion 9, the bottom surface of the substrate P can be supported by the upper surface of the first side plate 34 of the liquid recovery member 30.

The liquid recovery member 30 has an absorption member 36 that is capable of absorbing the liquid LQ having flowed out from the upper surface of the substrate P. The absorption member 36 includes a porous member. The absorption member 36 includes, for example, a spongy member or a porous member formed of a ceramic material. As the porous member, a sintered member in which a plurality of pores are formed (for example, a sintered metal), foam member (for example, a foam metal), or the like may be used. The absorption member 36 is arranged in the liquid holding portion 32 of the liquid recovery member 30. To be more specific, the absorption member 36 is arranged on the bottom surface 33A of the liquid recovery member 30. It is formed in an annular shape within the XY plane in accordance with the shape of the liquid holding portion 32. The liquid LQ having flowed out from the upper surface of the substrate P and flowed in the liquid holding portion 32 from the opening portion 31 of the liquid recovery member 30 is absorbed into and held in the absorption member 36 arranged in the liquid holding portion 32.

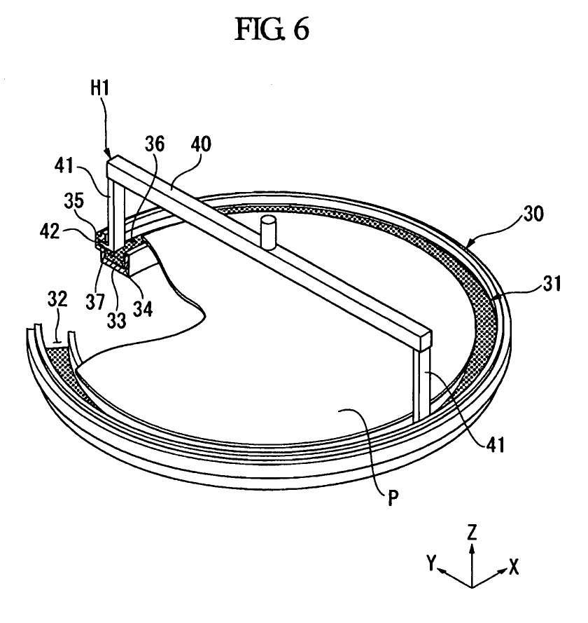

FIG. 6 is a partly cutaway view of a perspective view showing that a first transfer system H1 is transferring the liquid recovery member 30.

The liquid recovery member 30 has a recess portion 37 supported by the first transfer system H1. In the present embodiment, the recess portion 37 is an annular groove portion formed in the inner side surface (the second side surface 35A) of the second side plate 35 of the liquid recovery member 30. Note that the recess portion 37 may be formed in a part of a region in the circumferential direction of the second side plate 35 (the second side surface 35A).

The first transfer system H1 includes a support member 40 and two arm members 41 supported by the support member 40. In FIG. 6, the support member 40 is formed so as to extend in the Y axis direction. Each of the two arm members 41 is movable by an actuator (not shown in the figure) in the longitudinal direction of the support member 40 (the Y axis direction). The support member 40 that supports the arm members 41 is movable by an actuator (not shown in the figure) in a direction of six degrees of freedom of: the X axis, the Y axis, the Z axis, the θX, the θY and the θZ directions.

At a lower end of each of the arm members 41, there is formed a protrusion portion 42 capable of being arranged (inserted) inside the recess portion 37 of the liquid recovery member 30. The protrusion portions 42 are protruded substantially in parallel with the support member 40, in a direction in which the two arm members 41 are spaced apart wider from each other. In the first transfer system H1, arrangement (insertion) of the protrusion portions 42 of the arm members 41 inside the recess portions 37 of the liquid recovery member 30 allows the liquid recovery member 30 to be supported by the arm members 41. The control apparatus 3 moves the support member 40 while supporting the liquid recovery member 30 by means of the arm members 41 of the first transfer system H1. As a result, the liquid recovery member 30 is transferable (movable).

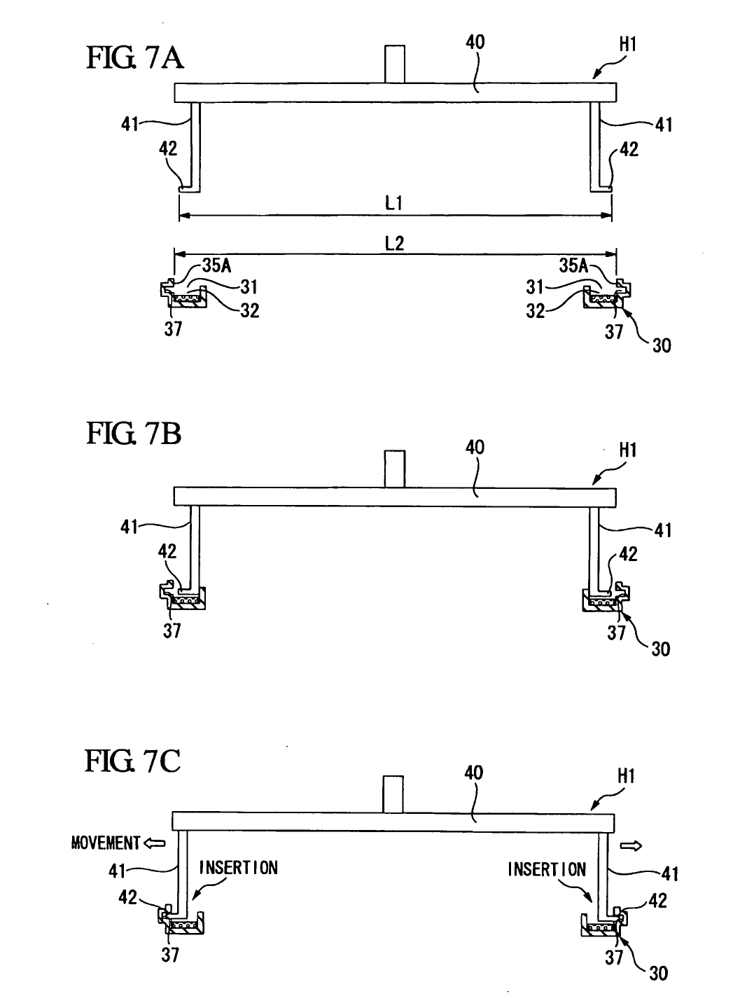

FIG. 7 are schematic diagrams showing an example of an operation of the first transfer system H1. Before supporting the liquid recovery member 30 by means of the first transfer system H1, the control apparatus 3 controls an actuator for moving the arm members 41, as shown in the schematic diagram of FIG. 7A. As a result, the two arm members 41 come closer to each other so that a distance L1 between tips of the two protrusion portions 42 becomes shorter than a diameter L2 of the annular second side surface 35A. After that, as shown in the schematic diagram of FIG. 7B, the control apparatus 3 controls the actuator for moving the support member 40 to adjust the relative positional relationship between the support member 40 supporting the arm members 41 and the liquid recovery member 30. As a result, the arm members 41 move inside the liquid holding portion 32 via the opening portion 31, causing the recess portion 37 of the liquid recovery member 30 to face the protrusion portions 42 of the arm members 41. Then, as shown in the schematic diagram of FIG. 7C, the control apparatus 3 controls the actuator for moving the arm members 41 to move the two arm members 41 so that both the two protrusion portions 42 of the first transfer system H1 are arranged (inserted) inside the recess portion 37 of the liquid recovery member 30, that is, in the direction in which the two arm members 41 are spaced apart wider from each other. As a result, the protrusion portions 42 of the arm members 41 are arranged (inserted) inside the recess portion 37 of the liquid recovery member 30, allowing the first transfer system H1 to be ready for supporting and transferring the liquid recovery member 30.

When stopping the support for the liquid recovery member 30 by the first transfer system H1, the control apparatus 3 brings the two arm members 41 closer and pulls the protrusion portions 42 of the arm members 41 out of the recess portion 37 of the liquid recovery member 30. At this time, from the state in which the protrusion portions 42 of the arm members 41 are arranged inside the recess portion 37 of the liquid recovery member 30, the distance L1 between the tips of the two protrusion portions 42 of the arm members 41 becomes shorter than the diameter L2 of the second side surface 35A. As a result, the support for the liquid recovery member 30 by the first transfer system H1 is stopped.

Furthermore, as shown in FIG. 6, the first transfer system H1 is capable of transferring the liquid recovery member 30 while holding the substrate P by means of the liquid recovery member 30. The first transfer system H1 is capable of transferring the liquid recovery member 30 together with the substrate P while holding the substrate P by means of the upper surface of the first side plate 34 of the liquid recovery member 30.

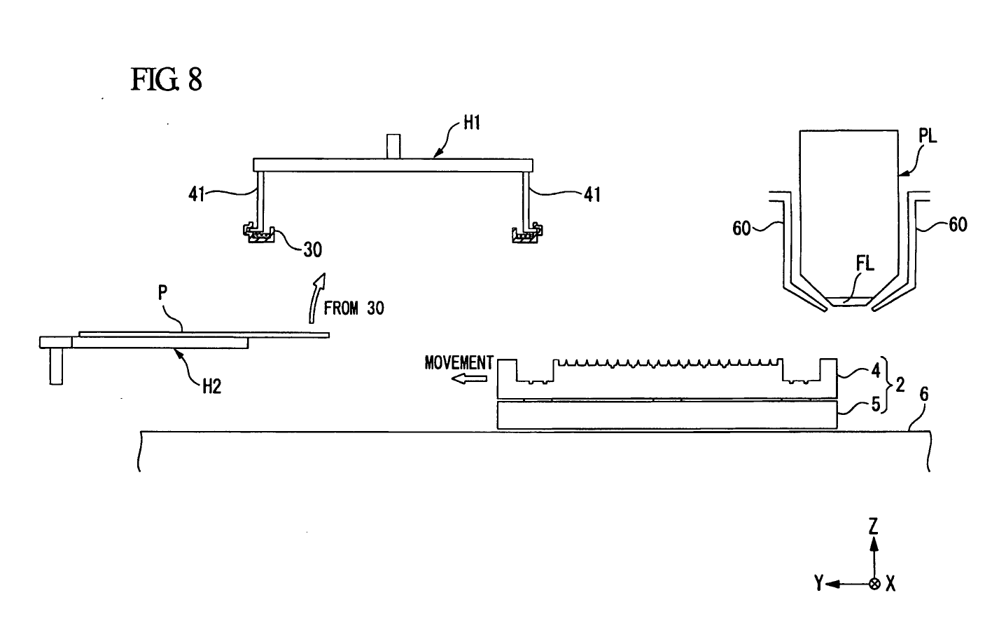

Next is a description of an example of a method for exposing the substrate P using an exposure apparatus EX with the aforementioned configuration, with reference to the schematic diagrams of FIG. 8 through FIG. 17.

A pre-exposure-processed substrate P is transferred from a coater/developer apparatus C/D (a coating apparatus not shown in the figure) to an exposure apparatus EX via an interface IF. As shown in FIG. 8, a second transfer system H2 supports the pre-exposure-processed substrate P having been carried in from the coater/developer apparatus C/D (the coating apparatus) via the interface IF. The first transfer system H1 carries out the liquid recovery member 30 from a container apparatus 70. In the container apparatus 70, a plurality of liquid recovery members 30 is contained. The control apparatus 3 uses the first transfer system H1 to carry out the liquid recovery member 30 from the container apparatus 70. The first transfer system H1 supports the liquid recovery member 30 having been carried out from the container apparatus 70.

Next, the control apparatus 3 controls at least either one of the first transfer system H1 and the second transfer system H2 to bring the first transfer system H1 supporting the liquid recovery member 30 and the second transfer system H2 supporting the substrate P close to each other. At this time, at a predetermined position distant from a projection optical system PL, the substrate P supported by the second transfer system H2 is transferred to the first transfer system H1. To be more specific, at a predetermined position, the second transfer system H2 mounts the substrate P onto the liquid recovery member 30 supported by the first transfer system H1. The second transfer system H2 transfers the substrate P to the first transfer system H1 so that the substrate P is mounted onto the upper surface of the first side plate 34 of the liquid recovery member 30 that is supported by the first transfer system H1. As a result, the substrate P is supported by the liquid recovery member 30 (the upper surface of the first side plate 34) that is supported by the first transfer system H1. The first transfer system H1 transfers the liquid recovery member 30 while supporting the substrate P by means of the liquid recovery member 30.

Next, the control apparatus 3 arranges the substrate stage 2 below the liquid recovery member 30 that is supported by the first transfer system H1. In the present embodiment, the control apparatus 3 uses a substrate stage driving unit 2D to move a substrate stage 2. As a result, the substrate stage 2 is arranged below the liquid recovery member 30 supported by the first transfer system H1 that is arranged at a predetermined position spaced away from the projection optical system PL.

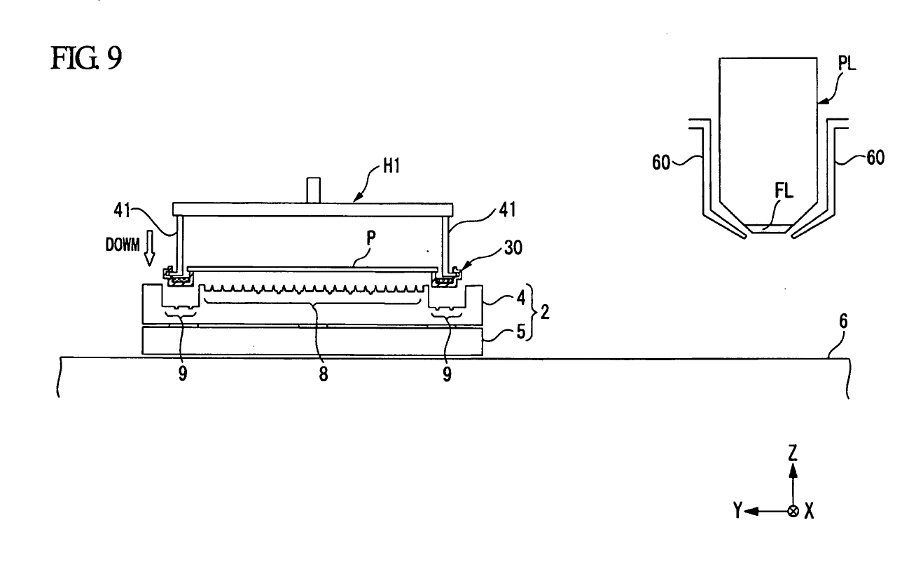

As shown in FIG. 9, the control apparatus 3 starts a carry-in operation of the substrate P and an attachment operation of the liquid recovery member 30 to the holder member 4 of the substrate stage 2. In the present embodiment, the control apparatus 3 performs a carry-in operation of the substrate P to the first holding portion 8 of the holder member 4 in parallel with at least a part of an attachment operation of the liquid recovery member 30 to the second holding portion 9 of the holder member 4. The control apparatus 3, while supporting the substrate P by means of the liquid recovery member 30, uses the first transfer system H1 to perform the carry-in operation of the substrate P to the first holding portion 8 of the holder member 4, and also to perform at least a part of the attachment operation of the liquid recovery member 30 to the second holding portion 9 of the holder member 4.

The control apparatus 3 uses the first transfer system H1 to transfer the substrate P together with the liquid recovery member 30 to the holder member 4. At this time, the substrate P is subjected to a transfer operation to the first holding portion 8 of the holder member 4 while being supported by the liquid recovery member 30. Furthermore, the liquid recovery member 30 is subjected to at least a part of the attachment operation to the second holding portion 9 of the holder member 4 while supporting the substrate P.

The control apparatus 3 controls at least either one of the first transfer system H1 and the substrate stage 2 so that the substrate P is held on the first holding portion 8 and so that the liquid recovery member 30 is held in the second holding portion 9. As a result, the positional relationship between the first transfer system H1 and the holder member 4 of the substrate stage 2 is adjusted, bringing the liquid recovery member 30 supported by the first transfer system H1 and the holder member 4 of the substrate stage 2 close to each other. The first transfer system H1 carries in the liquid recovery member 30 together with the substrate P to the holder member 4.

In the present embodiment, the first transfer system H1 carries in the liquid recovery member 30 supporting the substrate P to the holder member 4 from above the holder member 4. That is, the first transfer system H1 moves in the −Z direction (descends) while the first transfer system H1 that supports the liquid recovery member 30 in the state of supporting the substrate P is facing the holder member 4 of the substrate stage 2. Obviously, the substrate stage 2 may be moved in the +Z direction, or both of the two may be relatively moved.

The movement of the first transfer system H1 that, while supporting the substrate P, supports the liquid recovery member 30 in the −Z direction mounts the substrate P supported by the liquid recovery member 30 onto the first holding portion 8 of the holder member 4. After the substrate P is mounted onto the first holding portion 8 of the holder member 4, the first transfer system H1 further moves in the −Z direction. As a result, the upper surface of the first side plate 34 of the liquid recovery member 30 supported by the first transfer system H1 is brought out of contact with the bottom surface of the substrate P.

The first transfer system H1 further moves in the −Z direction after mounting the substrate P supported by the first side plate 34 of the liquid recovery member 30 onto the first holding portion 8 of the holder member 4 and bringing the first side plate 34 of the liquid recovery member 30 out of contact with the substrate P. As a result, the liquid recovery member 30 is mounted in the second holding portion 9 of the holder member 4.

After the liquid recovery member 30 is mounted in the second holding portion 9, the control apparatus 3 slightly moves the first transfer system H1 further in the −Z direction and at the same time adjusts the space between the two arm members 41 to pull the protrusion portions 42 of the arm members 41 out of the recess portion 37 of the second side plate 35. At this time, the distance L1 between the tips of the two protrusion portions 42 of the arm members 41 becomes shorter than the diameter L2 of the annular second side surface 35A. Next, the control apparatus 3 moves the first transfer system H1 in the +Z direction and pulls the protrusion portions 42 of the arm members 41 out of the liquid holding portion 32 of the liquid recovery member 30 to retract the first transfer system H1.

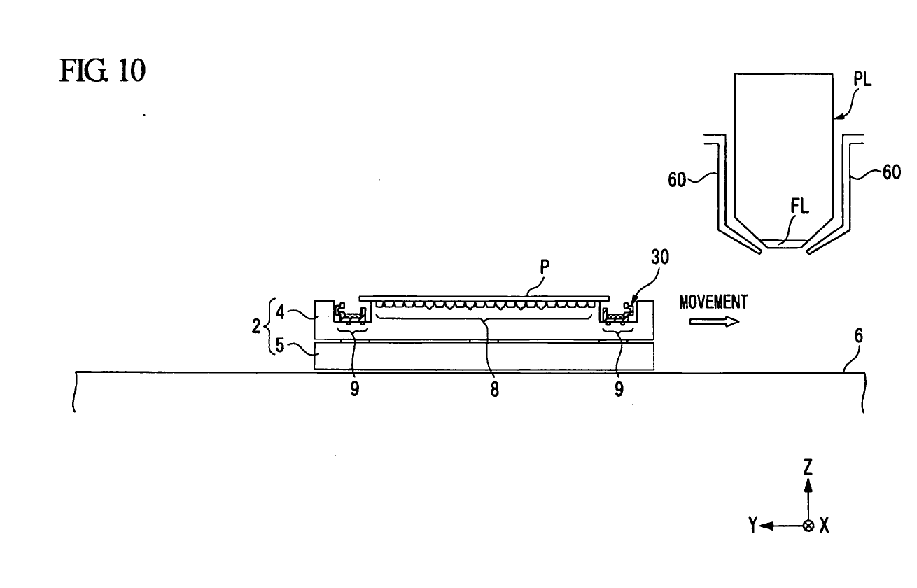

Furthermore, the control apparatus 3 performs a suction operation by means of the first suction ports 14 and the second suction ports 18 of the holder member 4. As a result, as shown in FIG. 10, the first holding portion 8 suction-and-holds the substrate P and at the same time the second holding portion 9 suction-and-holds the liquid recovery member 30.

After completion of the retraction of the first transfer system H1, the suction holding of the substrate P, and the suction holding of the liquid recovery member 30, the control apparatus 3 uses the substrate stage driving unit 2D to move the substrate stage 2. As a result, the substrate stage 2 holding the substrate P and the liquid recovery member 30 is arranged below the projection optical system PL so that an optical element FL of the projection optical system PL faces the substrate P held on the substrate stage 2.

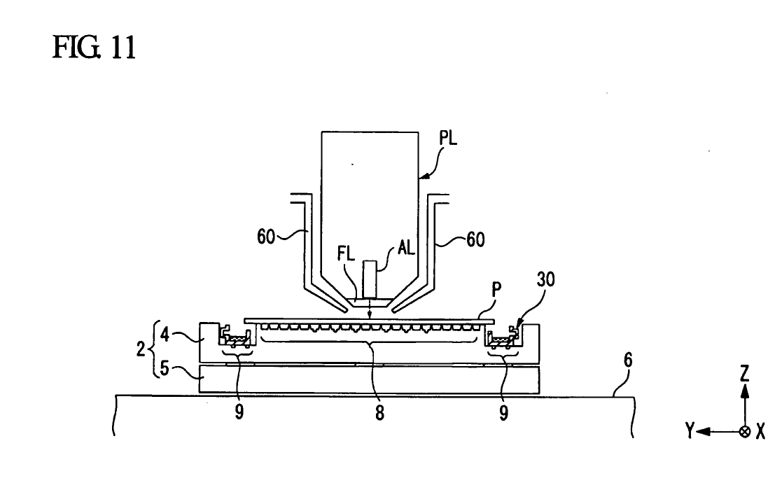

Then, the control apparatus 3 performs a predetermined process such as measurement of the positional information of the substrate P held on the substrate stage 2. For example, as shown in FIG. 11, the control apparatus 3 uses an alignment system AL to detect an alignment mark formed on the substrate P, or uses a focus leveling detection system (not shown in the figure) to detect surface position information of the upper surface (the surface) of the substrate P.

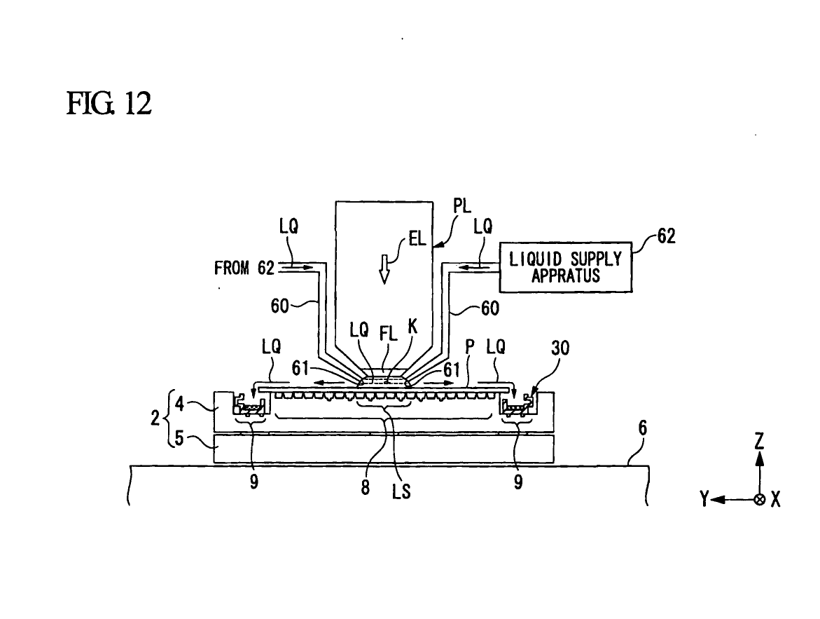

After performing the predetermined processing such as measurement of the positional information of the substrate P, the control apparatus 3 uses a liquid supply member 60 to form an immersion space LS, as shown in FIG. 12. To the liquid supply member 60, a liquid supply apparatus 62 is connected that is capable of sending a clean, temperature-adjusted liquid LQ. The liquid LQ sent from the liquid supply apparatus 62 flows in one end (upper end) of a supply passage formed inside the liquid supply apparatus 62, flows through the supply passage, and is then supplied to a liquid supply port 61 provided at the other end (lower end) of the supply passage. The liquid LQ, which has been sent from the liquid supply apparatus 62 and then supplied to the liquid supply port 61 via the supply passage of the liquid supply member 60, is supplied onto the substrate P via the liquid supply port 61.

In the present embodiment, as the liquid LQ, a liquid is used, whose refractive index with respect to the exposure light EL (the ArF excimer laser beam (wavelength: 193 nm)) is higher than that of the optical element FL. For example, in the case where the optical element FL is formed of silica glass, which has a refractive index of approximately 1.56 with respect to the exposure light EL, a liquid whose refractive index is higher than that of the exposure light EL from silica glass, that is, for example approximately 1.6 to 1.8, may be used as the liquid LQ. In the present embodiment, the optical element FL is formed of silica glass (SiO₂). As the liquid LQ, decalin (C₁₀H₁₈) is used. The refractive index of decalin with respect to the exposure light EL is higher than that of, for example, water with respect to the exposure light EL, and hence the resolution and the depth of focus can be favorably improved. Moreover, the heat of vaporization of decalin is sufficiently lower than, for example that of water, and hence using decalin as the liquid LQ can suppress change in the environment in which the exposure apparatus EX is situated (the environment in the chamber apparatus CH). Furthermore, in the present embodiment, the numerical aperture NA of the projection optical system PL is, for example, approximately 1.4, which is lower than the refractive index of the optical element FL with respect to the exposure light EL.

Note that decalin as used for the liquid LQ is an example. The type (property) of the liquid LQ used for the liquid immersion exposure is appropriately selectable according to fineness of the pattern projected onto the substrate P or the like. For example, water (pure water) may be used as the liquid LQ.

Examples of the liquid LQ may include for example: a liquid with isopropanol and glycerol, having a C—H bond and an O—H bond, and a liquid (organic solvent) such as hexane, heptane, and decane. Alternatively, this may be a liquid where two or more types of optional liquids of the predetermined liquids are mixed, or a liquid where a predetermined liquid is added to (mixed with) pure water. Alternatively, as the liquid LQ, one in which an acid or a base such as H⁺, Cs⁺, and K⁺, or Cl⁻, SO₄²⁻, and PO₄²⁻ is added to (mixed with) pure water may be used. Moreover, a liquid in which fine particles of for example Al oxide are added to (mixed with) pure water may be used. These liquids LQ are capable of passing an ArF excimer laser. Furthermore the liquid LQ is preferably one for which the light absorption coefficient is small, the temperature dependency is small, and which is stable with respect to the photosensitive material (or protection film (top coat film) or anti-reflection film) coated on the surface of the projection optical system PL and/or the substrate P. As the gas supplied to a gas space around the immersion space, one that does not change the materiality (refractive index) of the liquid LQ is selected according to the liquid LQ used.

As a material for forming the optical element FL, for example, barium lithium fluoride (BaLiF₃) may be used whose refractive index with respect to the exposure light EL is approximately 1.64. Furthermore, as a material for forming the optical element FL, fluorite (CaF₂), barium fluoride (BaF₂), or a monocrystalline material of another fluoride compound may be used. Moreover, sapphire, germanium dioxide, or the like as disclosed in PCT International Publication No. WO 2005/059617, or potassium chloride (refractive index: approximately 1.75) or the like as disclosed in PCT International Publication No. WO 2005/059618 may be used.

The liquid supply member 60 supplies the liquid LQ onto the upper surface of the substrate P held on the substrate stage 2 from above the substrate P. By supplying the liquid LQ from the liquid supply member 60 in the vicinity of the optical element FL of the projection optical system PL, the immersion space LS is formed so as to fill the optical path space K of the exposure light EL between the optical element FL of the projection optical system PL and the substrate P.

Then, the control apparatus 3 irradiates the exposure light EL onto the substrate P held on the holder member 4 via the liquid LQ in the immersion space LS to perform the liquid immersion exposure for the substrate P. In the present embodiment, the exposure apparatus EX is a scanning type exposure apparatus (a so-called scanning stepper) that projects the image of the pattern of the mask M onto the substrate P, while synchronously moving the mask M and the substrate P in the predetermined scanning direction. Here, the scanning direction (the synchronous movement direction) of the substrate P is made the Y axis direction. The scanning direction (the synchronous movement direction) of the mask M is also made the Y axis direction. A plurality of shot regions are provided on the substrate P. The control apparatus 3 moves the shot regions on the substrate P in the Y axis direction with respect to the projection region of the projection optical system PL, and, synchronously with the movement in the Y axis direction of the substrate P, moves the pattern formation region of the mask M in the Y axis direction with respect to the illumination region of the illumination system IL. By irradiating the exposure light EL onto the projection region via the projection optical system PL and the liquid LQ, the plurality of shot regions on the substrate P are sequentially exposed with the image of the pattern formed on the projection region.

A part of the liquid LQ having been supplied from the liquid supply member 60 onto the substrate P to form the immersion space LS flows on the upper surface of the substrate P. The liquid LQ having reached the edge of the upper surface of the substrate P flows out from the upper surface of the substrate P. The holder member 4 holds the liquid recovery member 30 in the second holding portion 9 so as to surround the substrate P. The liquid LQ having flowed out from the upper surface of the substrate P is recovered by the liquid recovery member 30. The opening portion 31 of the liquid recovery member 30 is arranged so that the liquid LQ from the upper surface of the substrate P flows therein. The liquid LQ having flowed out of the upper surface of the substrate P flows in the opening portion 31 of the liquid recovery member 30 by the effect of gravitation and the like. The liquid LQ having flowed in from the opening portion 31 of the liquid recovery member 30 is held in the recess-shaped liquid holding portion 32. That is, the liquid recovery member 30 can store the liquid LQ, which has flowed in from the opening portion 31, in the liquid holding portion 32. In the present embodiment, the liquid LQ is decalin, which has a low heat of vaporization as described above. Therefore, the liquid LQ (decalin) stored in the liquid holding portion 32 does not cause a large change in the environment in which the exposure apparatus EX is situated (the environment in the chamber apparatus CH).

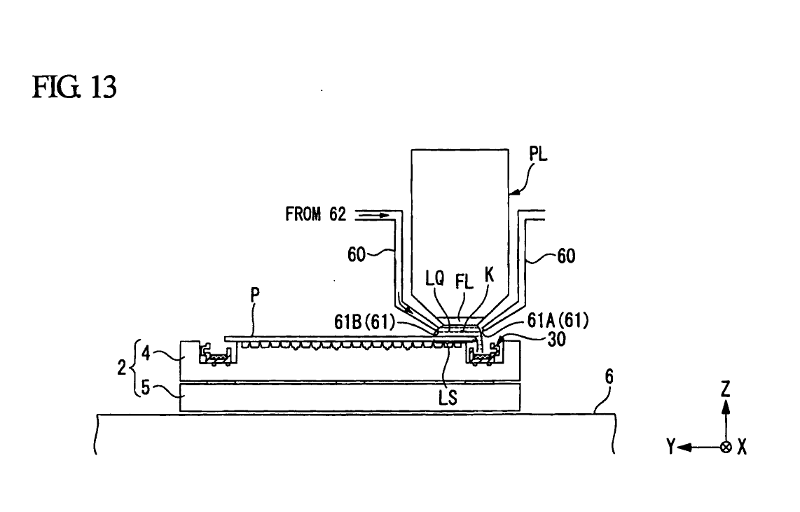

Furthermore, as shown in FIG. 13, in the case where the immersion space LS is formed in the peripheral region of the upper surface of the substrate P, for example, in order to immersion expose a shot region provided in the vicinity of the edge of the upper surface of the substrate P, the liquid LQ having flowed out from the upper surface of the substrate P is recovered by the liquid recovery member 30. Note that, in FIG. 13, the liquid LQ is supplied from two liquid supply ports 61A, 61B. It is possible to halt the liquid supply from one supply port or reduce the supply amount of the liquid from one supply port according to the positional relationship between the liquid supply ports 61A, 61B and the substrate stage 2 (the liquid recovery member 30). For example, as shown in FIG. 13, in the case where one liquid supply port (61A) does not face the substrate P, supply of the liquid LQ from the liquid supply port 61A may be stopped, or the supply amount of the liquid LQ may be reduced. That is, as shown in FIG. 13, the liquid LQ from the liquid supply port 61A arranged at a position facing the liquid recovery member 30 may be halted, or the supply amount of the liquid LQ may be reduced.

The width of the opening portion 31 of the liquid recovery member 30 (the gap between the first side surface 34A and the second side surface 35A) is optimized according to, for example, the moving speed of the substrate stage 2 when the substrate P is immersion exposed. In the case where the shot region in the vicinity of the edge of the substrate P held on the substrate stage 2, at least a part of the immersion space LS is more likely to be moved on the substrate stage 2 without facing the substrate P, if the moving speed of the substrate stage 2 is high. Therefore, the width of the opening portion 31 needs to be wide. In the present embodiment, the diameter (the size in the XY direction) of the immersion space LS is set to be approximately 120 mm; the width of the opening portion 31 of the liquid recovery member 30 is set to be approximately 50 mm. The substrate P has a diameter of approximately 300 mm.

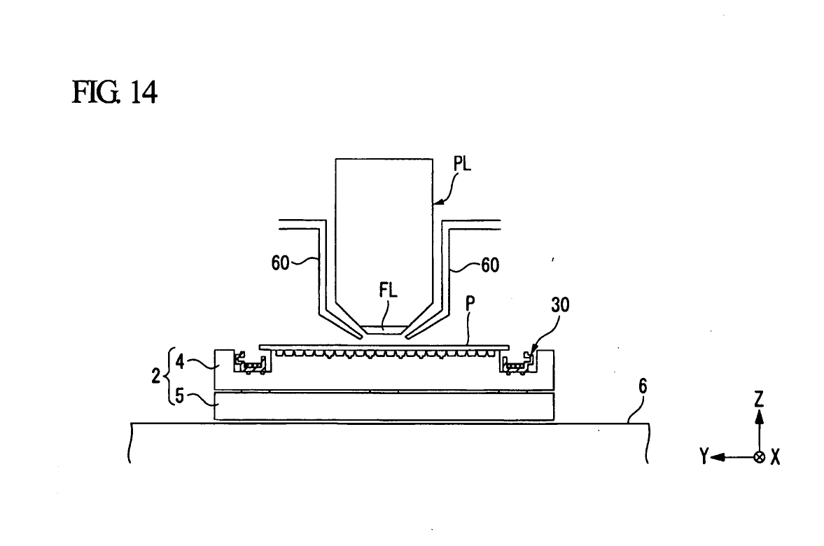

After completion of the liquid immersion exposure for the substrate P, the control apparatus 3 stops the liquid supply operation by the liquid supply member 60, as shown in FIG. 14. The control apparatus 3 then starts a carry-out operation of the substrate P from the holder member 4 of the substrate stage 2 and a removal operation of the liquid recovery member 30. In the present embodiment, the control apparatus 3 performs the carry-out operation of the substrate P from the first holding portion 8 of the holder member 4 in parallel with at least the removal operation of the liquid recovery member 30 from the second holding portion 9 of the holder member 4.

The first transfer system H1 is capable of transferring the liquid recovery member 30 while supporting the substrate P supported by means of the liquid recovery member 30. The control apparatus 3 uses the first transfer system H1 to perform the removal operation of the liquid recovery member 30 from the second holding portion 9 of the holder member 4. In parallel with at least a part of the removal operation, it also performs the carry-out operation of the substrate P from the first holding portion 8 of the holder member 4, while supporting the substrate P by means of the liquid recovery member 30.

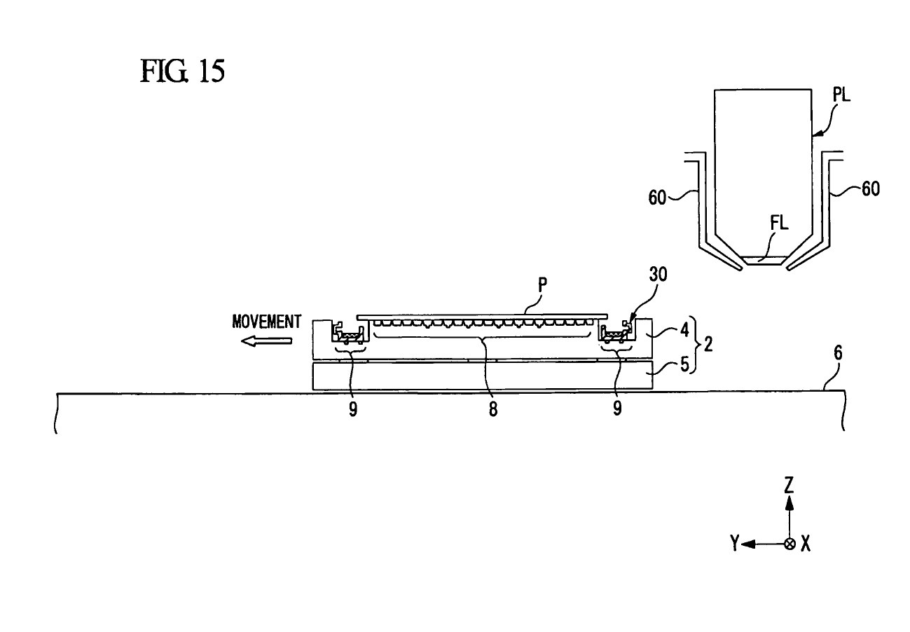

As shown in FIG. 15, the control apparatus 3 uses the substrate stage driving unit 2D to move the substrate stage 2, thereby arranging it at a predetermined position spaced away from the projection optical system PL. Furthermore, the control apparatus 3 stops the suction operation by the first suction ports 14 of the first holding portion 8 and the suction operation by the second suction ports 18 of the second holding portion 9 to make the substrate P transferable from the first holding portion 8 and also to make the liquid recovery member 30 removable from the second holding portion 9.

The control apparatus 3 then controls at least one of the first transfer system H1 and the substrate stage 2 to adjust the positional relationship between the first transfer system H1 and the holder member 4 of the substrate stage 2 in the XY direction. As a result, the arm members 41 of the first transfer system H1 and the liquid recovery member 30 held in the second holding portion 9 of the holder member 4 come closer (relatively move in the Z axis direction).

The control apparatus 3 brings the first transfer system H1 close to the liquid recovery member 30 held in the second holding portion 9 from above the holder member 4. At this time, to remove the liquid recovery member 30 from the second holding portion 9, the first transfer system H1 is moved in the −Z direction (is lowered) in a state with the first transfer system H1 and the holder member 4 facing each other, and both the protrusion portions 42 of the two arm members 41 are inserted into the liquid holding portion 32 of the liquid recovery member 30.

Next, the control apparatus 3 controls the actuator of the first transfer system H1 to move the arm members 41 of the first transfer system H1. As a result, the protrusion portions 42 of the arm members 41 are arranged (inserted) in (into) the recess portion 37 of the liquid recovery member 30.

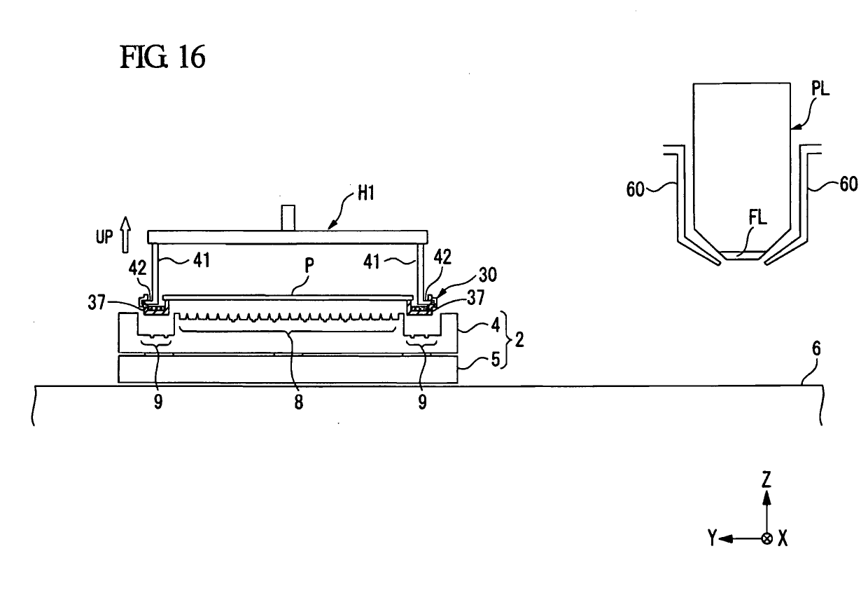

After inserting the protrusion portions 42 of the arm members 41 of the first transfer system H1 into the recess portion 37, the control apparatus 3 moves (raises) the first transfer system H1 in the +Z direction, as shown in FIG. 16. As a result, the arm members 41 of the first transfer system H1 support the liquid recovery member 30.

By the movement of the first transfer system H1 supporting the liquid recovery member 30 in the +Z direction, the liquid recovery member 30 moves off the second holding portion 9 of the holder member 4. By the further movement of the first transfer system H1 in the +Z direction after the liquid recovery member 30 is brought out of contact with the second holding portion 9 of the holder member 4, the upper surface of the first side plate 34 of the liquid recovery member 30 supported by the first transfer system H1 comes into contact with the overhang region PH of the bottom surface of the substrate P mounted on the first holding portion 8. The upper surface of the first side plate 34 of the liquid recovery member 30 supports the overhang region PH of the bottom surface of the substrate P supported by the first holding portion 8 of the holder member 4.

By the further movement of the first transfer system H1 in the +Z direction after the contact of the bottom surface of the substrate P supported by the first holding portion 8 of the holder member 4 with the upper surface of the first side plate 34 of the liquid recovery member 30, the substrate P is released from the first holding portion 8. The control apparatus 3 then supports the substrate P, which is supported by the first holding portion 8, by means of the liquid recovery member 30 supported by the first transfer system H1 to detach the substrate P from the first holding portion 8. After that, the control apparatus 3 controls the first transfer system H1 to carry out the liquid recovery member 30 together with the substrate P from the holder member 4.

Thus, in the present embodiment, the control apparatus 3 uses the first transfer system H1 to carry out the substrate P together with the liquid recovery member 30 from the holder member 4. The substrate P, while being supported by the liquid recovery member 30, is subjected to the carry-out operation from the first holding portion 8 of the holder member 4. The liquid recovery member 30, while supporting the substrate P, is subjected to at least a part of the removal operation from the second holding portion 9 of the holder member 4.

After carrying out the liquid recovery member 30 together with the substrate P from the holder member 4 by use of the first transfer system H1, the control apparatus 3 controls at least one of the first transfer system H1 and the second transfer system H2 to bring the first transfer system H1 supporting the liquid recovery member 30 in the state of supporting the post-exposure-processed substrate P and the second transfer system H2 close to each other. Then, at a predetermined position spaced away from the projection optical system PL, the control apparatus 3 transfers the substrate P supported by the liquid recovery member 30 that is supported by the first transfer system H1 over to the second transfer system H2. To be more specific, the second transfer system H2 receives the substrate P from the liquid recovery member 30 supported by the first transfer system H1.

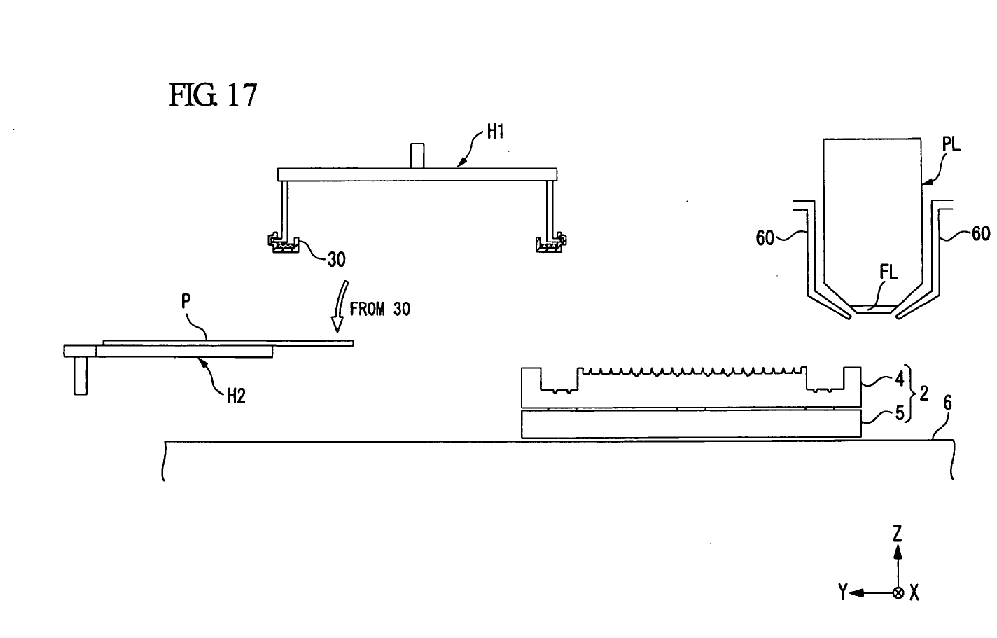

As a result, as shown in FIG. 17, the first transfer system H1 is in the state of supporting only the liquid recovery member 30 and the second transfer system H2 is in the state of supporting only the substrate P.

The post-exposure-processed substrate P is transferred to the vicinity of the connection portion with the interface IF by the second transfer system H2 and is carried out from the exposure apparatus EX. The post-exposure-processed substrate P having been transferred to the coater/developer apparatus C/D via the interface IF is subjected to a predetermined process such as a development process in the coater/developer apparatus C/D.

In the present embodiment, the post-exposure-processed substrate P, wet with the liquid LQ, is carried out from the substrate stage 2. As described above, in the present embodiment, a liquid with a low heat of vaporization is used as the liquid LQ, and hence the effect of the heat of vaporization of the liquid LQ on the substrate P is suppressed during transfer of the substrate P.

The liquid recovery member 30 that is removed of the substrate P by the second transfer system H2 is transferred to the container apparatus 70 by the first transfer system H1. The liquid recovery member 30 having been transferred to the container apparatus 70 is reused after, for example, a predetermined process including at least one of a removal (recovery) treatment of the liquid LQ held in the liquid holding portion 32, a cleaning treatment, and a drying treatment. Note that the used liquid recovery member 30 having been transferred to the container apparatus 70 may be replaced with a new one.

As described above, the liquid LQ having flowed out from the upper surface of the substrate P can be favorably recovered by the liquid recovery member 30. In the present embodiment, the liquid recovery member 30 is arranged so as to surround the substrate P. As a result, even if the liquid LQ flows out at any point on the edge of the upper surface of the substrate P, the flowed-out liquid LQ can be favorably recovered. Therefore, the liquid LQ that has flowed out from the substrate P can be prevented from being brought to the peripheral devices and the peripheral members, and deterioration in accuracy of the exposure operation and measurement operation that are performed in the exposure apparatus body S can be suppressed. For example, if the liquid LQ having flowed out from the substrate P is brought to the optical path of the measurement light from the laser interferometer 2L, to the reflection surface 2R, or the like, there is a possibility that measurement accuracy of the position of the substrate P may deteriorate, and consequently there is a possibility that a disadvantage may arise where exposure accuracy may be deteriorated. In the present embodiment, the liquid LQ can be favorably recovered by use of the liquid recovery member 30. Therefore, such a disadvantage can be prevented.

In the case where the liquid LQ on the substrate P is recovered, favorable recovery of the liquid LQ from above the substrate P may be difficult according to the type (materiality) of liquid. For example, in the case where the liquid recovery port for recovering the liquid LQ on the substrate P is arranged at a position facing the upper surface of the substrate P, it may be difficult to suction up the liquid LQ by use of the liquid recovery port arranged at a position facing the upper surface of the substrate P, according to, for example, the viscosity of the liquid LQ or the contact angle of the liquid LQ with respect to the upper surface of the substrate P. Especially, in the case where a so-called local liquid immersion method is adopted in which a liquid supply port and a liquid recovery port that are arranged at positions facing the upper surface of a substrate P are used to form an immersion space so as to cover a part of the region on the upper surface of the substrate P with a liquid LQ, the liquid LQ cannot be favorably recovered by use of the liquid recovery port arranged at a position facing the upper surface of the substrate P, according to, for example, the viscosity of the liquid LQ, the contact angle of the liquid LQ with respect to the upper surface of the substrate P, or the like, and hence it will be difficult to cover only a part of the region on the upper surface of the substrate P with the liquid LQ.

In the present embodiment, the liquid recovery member 30 is arranged around the substrate P, and the opening portion 31 of the liquid recovery member 30 is arranged so that the liquid LQ from the upper surface of the substrate P flows therein. As a result, even in the case where a various types (materialities) of liquids LQ are used to form the immersion space LS, those liquids LQ can be favorably recovered. In other words, limitations in the types (materialities) of liquids LQ usable for liquid immersion exposure can be lifted, thereby offering broader choices. Furthermore, for example, efforts can be saved for selecting or developing a material, for setting the contact angle of the liquid LQ with respect to the upper surface of the substrate P to a desired value, which is made into a film for forming the upper surface of the substrate P (for example, the aforementioned topcoat film, or a film of a photosensitive material).

Furthermore, in the present embodiment, the liquid recovery member 30 is held in a part of the holder member 4 holding the substrate P and is arranged around the substrate P. As a result, the members that are arranged around the optical element FL is prevented from becoming larger or more complex. In the case where the optical element FL becomes larger as the numerical aperture of the projection optical system PL increases in number, there is a possibility that the exposure apparatus EX as a whole or in part becomes larger if even the members that are arranged around the enlarged optical element FL become larger or more complex. In the present embodiment, the members that are arranged around the optical element FL are prevented from becoming larger or more complex. Therefore, even if the optical element FL becomes larger, the exposure apparatus EX as a whole or in part is prevented from becoming larger.

The liquid recovery member 30 is detachably held in the second holding portion 9 of the holder member 4, and hence the liquid recovery member 30 can be transferred. Therefore, after the liquid immersion exposure for the substrate P, by removing the liquid recovery member 30 from the second holding portion 9 to be transferred to a predetermined position such as the container apparatus 70, predetermined processing such as removing (disposing of) the liquid LQ accumulated in the liquid holding portion 32 or cleaning the liquid recovery member 30 can be smoothly performed at a position spaced away from the exposure apparatus body S. Furthermore, a deteriorated liquid recovery member 30 can be easily replaced with a new one.

Furthermore, in the present embodiment, it is configured such that the liquid recovery member 30 is detachably held in the second holding portion 9 which is different from the first holding portion 8 holding the substrate P and that the liquid LQ is not brought to the first holding portion 8 holding the substrate P. Therefore, a conventional substrate holding mechanism such as a pin chuck structure can be used in the first holding portion 8 holding the substrate P.

Furthermore, in the present embodiment, the liquid recovery member 30 is capable of supporting the substrate P by means of the first side plate 34, and the first transfer system H1 can transfer the liquid recovery member 30 together with the substrate P while supporting the substrate P by means of the liquid recovery member 30. Moreover, the carry-in operation of the substrate P to the holder member 4 can be performed in parallel with at least a part of the attachment operation of the liquid recovery member 30 to the holder member 4 and also the carry-out operation of the substrate P from the holder member 4 can be performed in parallel with at least a part of the detachment operation of the liquid recovery member 30 from the holder member 4.

Furthermore, in the present embodiment, the carry-in operation of the substrate P to the holder member 4 and the carry-out operation of the substrate P from the holder member 4 are performed in the state with the substrate P held by the liquid recovery member 30. As a result, for example, a mechanism, as disclosed in Japanese Unexamined Patent Application, First Publication No. 2005-12009, which includes a lift pin and the like for raising and lowering the substrate P to transfer the substrate P to the holder member can be omitted. Furthermore, an actuator for driving the lift pin, or cables for supplying power to the actuator can also be omitted. Therefore, the substrate stage 2 can be made lighter and simpler. Moreover, controllability of the position of the substrate stage 2 (and consequently alignment accuracy of the substrate stage 2) can be improved.

Furthermore, in the present embodiment, the absorption member 36 is arranged in the liquid holding portion 32, and hence at least a part of the liquid LQ having flowed in the liquid holding portion 32 via the opening portion 31 is absorbed by the absorption member 36. Therefore, the liquid LQ held in the liquid holding portion 32 is prevented from being scattered to the outside of the liquid recovery member 30 via the opening portion 31. In the case where the liquid recovery member 30 is moved along with the movement of the holder member 4 in the condition that the liquid LQ is accumulated in the liquid holding portion 32, there is a possibility that vibration will occur because of the movement of the liquid LQ inside the liquid holding portion 32 or the rippling of the surface of the liquid LQ. In the present embodiment, occurrence of vibration can be suppressed by absorbing the liquid LQ into the absorption member 36. Therefore, favorable exposure accuracy and measurement accuracy can be maintained.

In the case where there is a low possibility that the liquid LQ recovered by the liquid recovery member 30 will be scattered such as when the amount of the liquid LQ flowing in the liquid recovery member 30 is small, the absorption member 36 may be omitted.

Furthermore, in the present embodiment, the substrate P held on the first holding portion 8 and the liquid recovery member 30 held in the second holding portion 9 is spaced apart. Therefore, deformation of the substrate P due to the liquid recovery member 30 can be suppressed.

In the case where deformation of the substrate P can be suppressed, the upper surface of the first side plate 34 of the liquid recovery member 30 may be in contact with the underside surface of the substrate P.

### Second Embodiment

Next is a description of a second embodiment. In the following description, components the same as or similar to those of the aforementioned first embodiment are denoted by the same reference symbols, and description thereof is simplified or omitted.

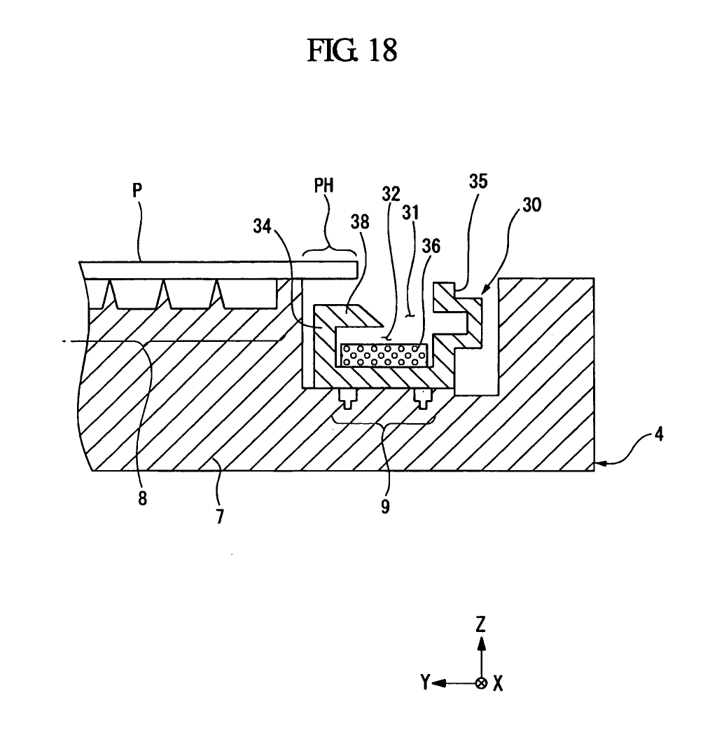

FIG. 18 is an enlarged view of a part of a side cross-sectional view showing a vicinity of the substrate stage 2 according to the second embodiment. In the aforementioned first embodiment, the liquid recovery member 30 is held in the second holding portion 9 so that a part of the opening portion 31 faces the bottom surface of the substrate P held on the first holding portion 8. However, a characteristic point of the present embodiment lies in that the opening portion 31 does not face the bottom surface of the substrate P.

In the present embodiment, the holder member 4 holds the liquid recovery member 30 in the second holding portion 9 so that at least a part of the liquid recovery member 30 and the overhang region PH of the bottom surface of the substrate P held by the first holding portion 8 face each other and also that the opening portion 31 of the liquid recovery member 30 and the overhang region PH of the bottom surface of the substrate P does not face each other. As shown in FIG. 18, in the present embodiment, a flange member 38 that extends toward the second side plate 35 is formed at the upper end of the first side plate 34 of the liquid recovery member 30. An upper surface of the flange member 38 and the overhang region PH of the bottom surface of the substrate P face each other. Furthermore, a predetermined region of the upper surface of the flange member 38 is an inclined surface that is inclined in the −Z direction toward the outside of the liquid recovery member 30.

The liquid LQ having flowed out from the upper surface of the substrate P is supplied to the upper surface of the flange member 38 of the liquid recovery member 30, flows along the inclined surface of the upper surface of the flange member 38, and then flows in the opening portion 31. The liquid LQ having flowed in from the opening portion 31 is held in the liquid holding portion 32.

As described above, it is possible to arrange the liquid recovery member 30 so that at least a part of the liquid recovery member 30 faces the bottom surface of the substrate P held on the first holding portion 8 and that the opening portion 31 does not face the bottom surface of the substrate P.

In the present embodiment, the liquid recovery member 30 is capable of supporting the bottom surface of the substrate P by means of the upper surface of the flange member 38. The first transfer system H1 is capable of transferring the liquid recovery member 30 while supporting the substrate P by means of the flange member 38 of the liquid recovery member 30. Similarly to the aforementioned first embodiment, the first transfer system H1 is capable of carrying in the substrate P, together with the liquid recovery member 30, to the holder member 4 and is also capable of carrying out the substrate P from the holder member 4.

### Third Embodiment

Next is a description of a third embodiment. In the following description, components the same as or similar to those of the abovementioned embodiments are denoted by the same reference symbols, and description thereof is simplified or omitted.

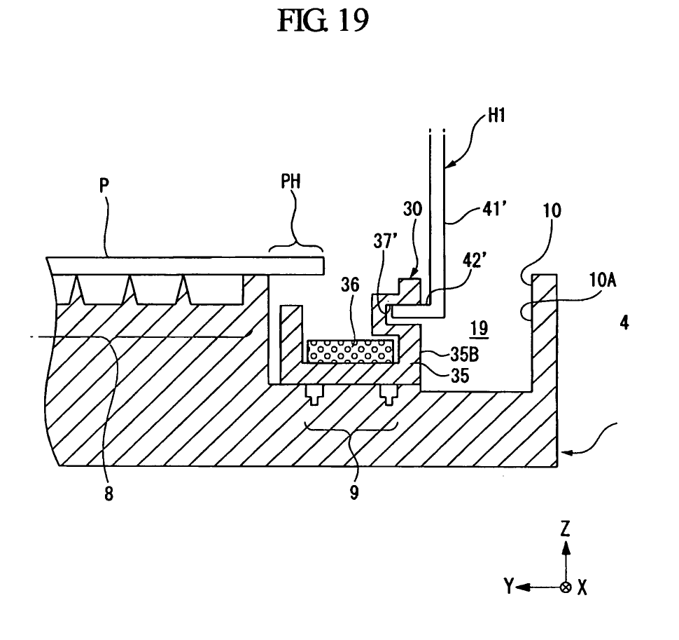

FIG. 19 is an enlarged view of part of a side cross-sectional view showing a vicinity of a substrate stage 2 according to the third embodiment. As shown in FIG. 19, the liquid recovery member 30 has a recess portion 37′ that is supported by the first transfer system H1. In the present embodiment, the recess portion 37′ is an annular groove portion that is formed in the outer side surface 35B of the second side plate 35 of the liquid recovery member 30. At a lower end of each of arm members 41′ of the first transfer system H1, a protrusion portion 42′ is formed that is capable of being arranged inside the recess portion 37 of the liquid recovery member 30. The protrusion portions 42′ protrude, substantially in parallel with the support member 40, in the direction in which the two arm members 41′ come closer to each other so as to be arranged inside the recess portion 37′ of the liquid recovery member 30. The recess portion 10 of the holder member 4 of the present embodiment is formed in a large size. Between the second side plate 35 (the outer side surface 35B) of the liquid recovery member 30 held in the second holding portion 9 and an inner side surface 10A of a recess portion 10 of the holder member 4, there is formed a space 19 in which the arm members 41′ is capable of being arranged. In this manner, the recess portion to be supported by the first transfer system H1 may be formed on the outer circumferential surface of the liquid recovery member 30. Note that the recess portion 37′ may be formed only in a part of a region in the circumferential direction of the second side plate 35 (the outer side surface 35B).

### Fourth Embodiment

Next is a description of a fourth embodiment. In the following description, components the same as or similar to those of the aforementioned embodiments are denoted by the same reference symbols, and description thereof is simplified or omitted.

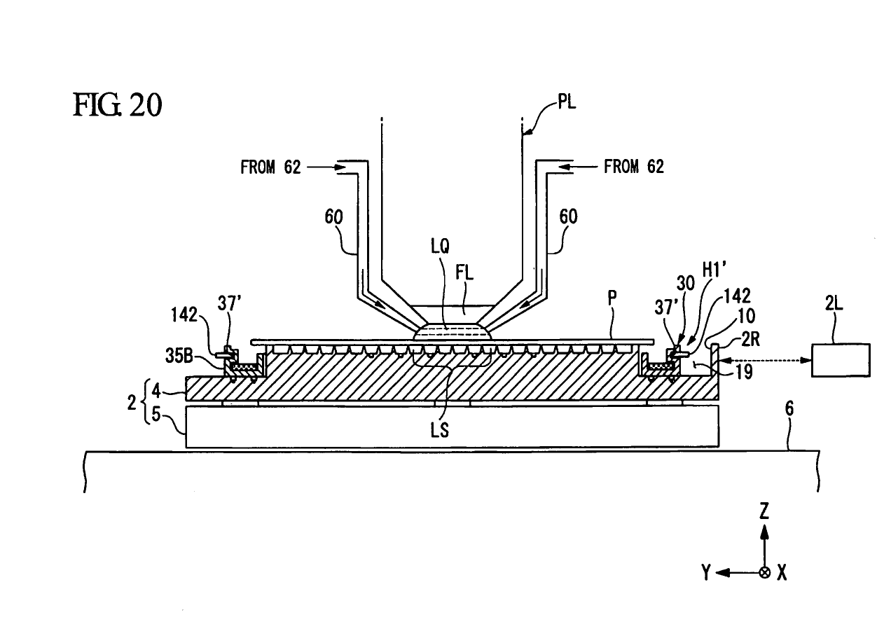

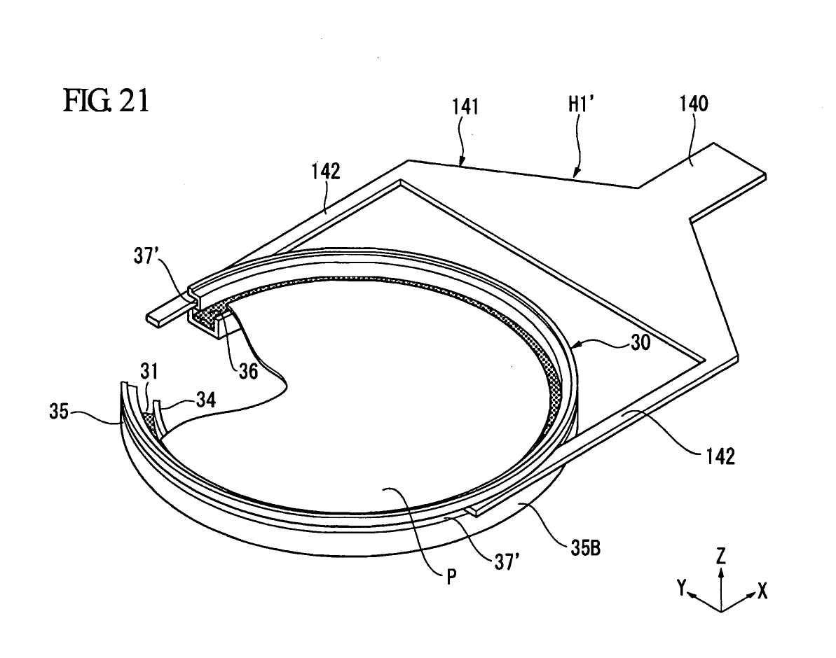

FIG. 20 is a side cross-sectional view showing a vicinity of a substrate stage 2 according to a fourth embodiment. FIG. 21 is a partly cutaway view of a perspective view showing that a first transfer system H1′ according to the fourth embodiment is transferring the liquid recovery member 30.

The liquid recovery member 30 according to the present embodiment has the recess portion 37′ similar to the aforementioned third embodiment, that is formed in the outer circumferential surface of the liquid recovery member 30 (the outer side surface 35B of the second side plate 35). Also similar to the aforementioned third embodiment, the liquid recovery member 30 is capable of supporting the substrate P. Furthermore, as shown in FIG. 20, on the −Y side of the liquid recovery member 30 held on the substrate stage 2 (the holder member 4), a space 19 is formed between the liquid recovery member 30 and the inner side surface 10A of the recess portion 10 of the holder member 4. That is, in the present embodiment, as shown in FIG. 20, the holder member 4 on the +Y side of the liquid recovery member 30 is partly cut out so as to allow at least a part the first transfer system H1′ to be arranged.

As shown in FIG. 21, the first transfer system H1′ according to the present embodiment includes a support member 140 and a fork-shaped arm member 141 that is supported by the support member 140. The fork-shaped arm member 141 has two fork portions (protrusion portions) 142 that extend in the −X direction in the figure. The arm member 141 including the two fork portions 142 is movable by an actuator (not shown in the figure) in a direction of six degrees of freedom of: the X axis, the Y axis, the Z axis, the θX, the θY and the θZ directions.

A part of each of the fork portions 142 is capable of being arranged inside the recess portion 37′ of the liquid recovery member 30 by relatively moving the arm member 141 and the liquid recovery member 30 in the XY direction. By arranging the fork portions 142 of the arm member 141 inside the recess portion 37′ of the liquid recovery member 30, the first transfer system H1′ is capable of supporting the liquid recovery member 30 by means of the arm member 141. The control apparatus 3 is capable of transferring (moving) the liquid recovery member 30 by moving the arm member 141 of the first transfer system H1′, in the state with the liquid recovery member 30 held by the arm member 141.

In the case where stopping the support of the liquid recovery member 30 by the first transfer system H1′, the actuator for moving the arm member 141 may be controlled to move the fork portions 142 in the XY direction and pull out the fork portions 142 from inside the recess portion 37′ of the liquid recovery member 30.

Thus, the fork-shaped first transfer system H1′ may be used to transfer the liquid recovery member 30 in the state with the substrate P supported by the liquid recovery member 30.

### Fifth Embodiment

Next is a description of a fifth embodiment. In the following description, components the same as or similar to those of the aforementioned embodiments are denoted by the same reference symbols, and description thereof is simplified or omitted.

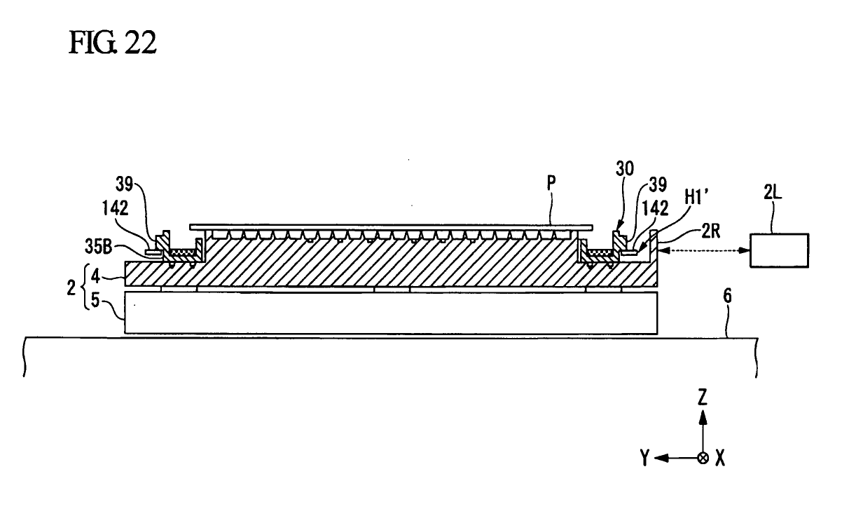

FIG. 22 is a side cross-sectional view showing a vicinity of a substrate stage 2 according to a fifth embodiment. In the aforementioned fourth embodiment, a groove portion is provided in the outer side surface 35B of the second side plate 35 of the liquid recovery member 30, and the groove portion is used to support the liquid recovery member 30 by means of the first transfer system H1′. On the other hand, in the fifth embodiment, as shown in FIG. 22, a protrusion portion 39 is provided on the outer side surface 35B of the second side plate 35 of the liquid recovery member 30, and the protrusion portion 39 can be used to support the liquid recovery member 30 by means of the first transfer system H1′. In the case where the liquid recovery member 30 is supported (transferred) by use of the protrusion portion 39 of the outer side surface 35B of the second side plate 35 of the liquid recovery member 30, the first transfer system H1 as described in the aforementioned third transfer system may be used.

### Sixth Embodiment

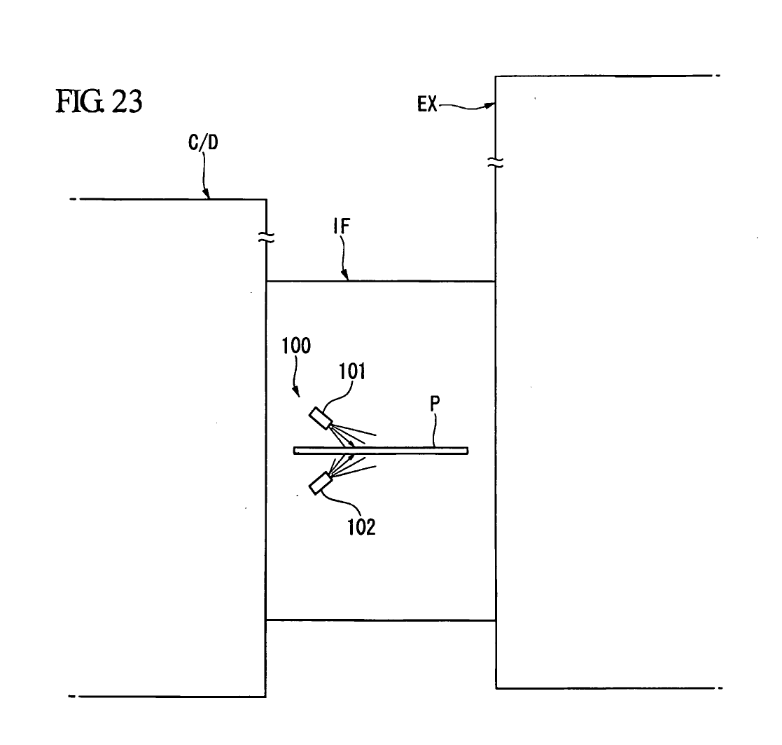

Next is a description of a sixth embodiment. FIG. 23 schematically shows an exposure apparatus EX according to the sixth embodiment. In the present embodiment, part way along a transfer path of the post-exposure-processed substrate P, there is provided a liquid removal apparatus 100 as disclosed in, for example, PCT International Publication No. WO 2004/102646 (corresponding to U.S. Patent Application Publication No. 2006/0152698) and U.S. Patent Application Publication No. 2005/225735. In the present embodiment, the liquid removal apparatus 100 is provided in an interface IF between the exposure apparatus EX and the coater/developer apparatus C/D. The liquid removal apparatus 100 includes: a first blow off unit 101 that, by blowing a gas onto the upper surface of the substrate P held on a holding member (not shown in the figure), blows off and removes the liquid LQ attached to the upper surface of the substrate P; and a second blow off unit 102 that, by blowing a gas to the bottom surface of the substrate P, blows and removes the liquid LQ attached to the bottom surface of the substrate P. Only the post-exposure-processed substrate P is transferred to the interface IF by the second transfer system H2. The liquid removal apparatus 100 removes the liquid LQ that is attached to (left on) the surface of the substrate P having been transferred to the interface IF. The substrate P having been subjected to a removal treatment of the liquid LQ by the liquid removal apparatus 100 is transferred to the coater/developer apparatus C/D and is subjected to a predetermined process such as a development treatment. Note that a method for removing the liquid is not limited to blowing a gas onto the substrate P. For example, various types of methods as disclosed in PCT International Publication No. WO 2004/102646 (corresponding to U.S. Patent Application Publication No. 2006/0152698) and U.S. Patent Application Publication No. 2005/225735 may be adopted.

Thus, the liquid removal apparatus 100 for removing the liquid LQ attached to the substrate P can be provided at a predetermined position in the transfer path between the exposure apparatus body S of the exposure apparatus EX and the coater/developer apparatus C/D.

In the present embodiment, the liquid removal apparatus 100 is provided in the interface IF. However, it may be provided inside the exposure apparatus EX (inside the chamber apparatus CH), or may be arranged inside the coater/developer apparatus C/D.

In the aforementioned first through sixth embodiments, the first holding portion 8 that detachably holds the substrate P and the second holding portion 9 that detachably holds the liquid recovery member 30 are provided in the single holder member 4. In another embodiment, a member in which the first holding portion 8 is provided and a member in which the second holding portion 9 is provided may be different from each other.

In the aforementioned respective embodiments, the first transfer system (H1, H1′) performs both the carry-in operation of the liquid recovery member 30 to the holder member 4 and the carry-out operation of the liquid recovery member 30 from the holder member 4, and also performs both the carry-out operation of the liquid recovery member 30 from the container apparatus 70 and the carry-in operation of the liquid recovery member 30 to the container apparatus 70. In another embodiment, for example, a third transfer system different from the first transfer system (H1, H1′) may be provided, and the third transfer system may be used to perform at least either one of the carry-in operation of the liquid recovery member 30 to the holder member 4 and the carry-out operation of the liquid recovery member 30 from the holder member 4. Moreover, the third transfer system may be used to perform at least either one of the carry-out operation of the liquid recovery member 30 from the container apparatus 70 and the carry-in operation of the liquid recovery member 30 to the container apparatus 70.

In the aforementioned respective embodiments, the control apparatus 3 uses the first transfer system (H1, H1′) to carry out the liquid recovery member 30 together with the substrate P from the holder member 4 and to transfer the substrate P supported by the liquid recovery member 30 that is supported by the first transfer system H1 to the second transfer system H2 at a predetermined position spaced away from the projection optical system PL, and subsequently uses the first transfer system H1 to transfer the liquid recovery member 30 to the container apparatus 70 and uses the second transfer system H2 to transfer the substrate P. In another embodiment, for example, the liquid recovery member 30 in the state of supporting the substrate P may be transferred, together with the substrate P, to the coater/developer apparatus C/D. Then, in the coater/developer apparatus C/D, a treatment for removing (throwing away) the liquid LQ held in the liquid holding portion 32 of the liquid recovery member 30, a treatment for cleaning the used liquid recovery member 30, or a treatment for replacing the used liquid recovery member 30 with a new one can be performed.

In the aforementioned first through sixth embodiments, the carry-in operation of the liquid recovery member 3 to the substrate stage 2 (the holder member 4) and/or the carry-out operation of the liquid recovery member 3 from the substrate stage 2 (the holder member 4) are performed in the state with the substrate P supported by the liquid recovery member 30. In another embodiment, the carry-in operation and/or the carry-out operation of the substrate P to and/or from the substrate stage 2 may be performed separately from the carry-in operation and/or the carry-out operation of the liquid recovery member 30 to and/or from the substrate stage 2 (the holder member 4). For example, the pre-exposure-processed substrate P may be carried in to the substrate stage 2 after the liquid recovery member 30 is carried in to the substrate stage 2, and the liquid recovery member 30 may be carried out after the post-exposure-processed substrate P is carried out from the substrate stage 2. In this case, transfer of the substrate P and transfer of the liquid recovery member 30 may be performed using the same transfer system, or may be performed using separate transfer systems.

In the aforementioned respective embodiments, the carry-in operation of the liquid recovery member 30 to the substrate stage 2 (the holder member 4) and the carry-out operation of the liquid recovery member 30 from the substrate stage 2 are performed for every exposure process for a single substrate. However, the carry-in operation of the liquid recovery member 30 to the substrate stage 2 and the carry-out operation of the liquid recovery member 30 from the substrate stage 2 may be performed for every exposure process for a plurality of substrates.

In the aforementioned respective embodiments, the description has been made referring to the case where the exposure apparatus EX is a single-stage-type exposure apparatus that includes a single substrate stage by way of example. However, a multiple-stage-type exposure apparatus, as disclosed in Japanese Unexamined Patent Application, First Publication No. H10-163099, Japanese Unexamined Patent Application, First Publication No H10-214783, Published Japanese Translation No. 2000-505958 of PCT International Publication, U.S. Pat. No. 6,341,007, U.S. Pat. No. 6,400,441, U.S. Pat. No. 6,549,269, U.S. Pat. No. 6,590,634, etc., that includes a plurality of substrate stages may be adopted. In this case, it is preferable that the liquid recovery member 30 be attachable to or detachable from any of the plurality of substrate stages.

Furthermore, the exposure apparatus EX may be an exposure apparatus including a substrate stage for holding a substrate, and a measurement stage on which is mounted a reference member formed with a reference mark, and various photoelectronic sensors, as disclosed in Japanese Unexamined Patent Application, First Publication No. H11-135400, Japanese Unexamined Patent Application, First Publication No 2000-164504, U.S. Pat. No. 6,897,963, etc. Moreover, the exposure apparatus EX may be an exposure apparatus including a plurality of substrate stages and measurement stages.

In the aforementioned respective embodiments, position information for the mask stage and the substrate stage is measured using an interference system. However, the invention is not limited to this and for example, an encoder system which detects a scale (grating) provided on the upper surface of the substrate stage may be used. In this case, preferably a hybrid system is adopted that includes both of an interference system and an encoder system, and calibration of the measurement results of the encoder system is performed using the measurement results of the interference system. Moreover, position control of the substrate stage may be performed using the interference system and the encoder system interchangeably, or using both.

Furthermore, it is possible to provide at least either one of the reference member and the photoelectronic sensors on the substrate stage 2. For example, at least either one of the reference member and the photoelectronic sensors can be arranged on a part of the upper surface 4F outside the recess portion 10 of the holder member 4, as shown in FIG. 3 and FIG. 4.

In the aforementioned respective embodiments, the description has been made referring to the case where the immersion space LS is formed between the optical element FL and the upper surface of the substrate P. However, the immersion space LS can be formed, on the image plane side of the projection optical system PL, between the optical element FL and a surface of an object arranged at a position facing the optical element FL. For example, immersion space LS can be formed between the optical element FL and the upper surface 4F of the holder member 4 arranged at a position facing the optical element FL.

Furthermore, it is possible to provide at least either one of the reference member and the photoelectronic sensors on the liquid recovery member 30. Moreover, it is also possible to transfer the liquid recovery member 30 in the condition that at least either one of the reference member and the photoelectronic sensors is installed on the liquid recovery member 30. For example, in the case where a measurement process is performed using at least either one of the reference member and the photoelectronic sensors, the liquid recovery member 30 installed with at least either one of the reference member and the photoelectronic sensors is attached on the holder member 4 by use of the first transfer system H1. Then the measurement process can be performed using at least either one of the reference member and the photoelectronic sensors installed on the liquid recovery member 30 that is attached on the holder member 4.

In the aforementioned respective embodiments, an exhaust mechanism may be provided, for example, in the vicinity of the opening portion 31 of the liquid recovery member 30. For example, when a part of the liquid LQ held in the liquid holding portion 32 is vaporized, the exhaust mechanism can exhaust the vaporized gas that is generated from the liquid LQ in the liquid holding portion 32 and is emitted to the outside of the liquid recovery member 30 via the opening portion 31. For example, in the case where a gas generated from the liquid LQ may have effect on the peripheral apparatuses, peripheral members, and the like, the gas can be exhausted by the exhaust mechanism, thereby suppressing the effect on the peripheral apparatuses, peripheral members, and the like, and maintaining exposure accuracy, measurement accuracy, and the like. Moreover, to prevent the gas generated from the liquid LQ that is held in the liquid holding portion 32 from being emitted to the outside of the liquid recovery member 30 via the opening portion 31, an inert gas such as nitrogen and helium may be supplied to, for example, the vicinity of the opening portion 31.

In the aforementioned respective embodiments, the liquid recovery member 30 may be arranged around the substrate P and, at the same time, a second liquid recovery member having a liquid recovery port capable of recovering the liquid LQ on the substrate P may be arranged at a position facing the upper surface of the substrate P that is held on the holder member 4.

In the aforementioned respective embodiments, exhaust port(s) may be provided at least one position on the upper surface of the first side plate 34 of the liquid recovery member 30; and when the substrate P is supported by the liquid recovery member 30, the exhaust port(s) may be connected with a vacuum apparatus including a vacuum pump to vacuum chuck the substrate P to the upper surface of the first side plate 34 of the liquid recovery member 30. In this case, an exhaust passage that communicates with the exhaust port(s) in the upper surface of the first side plate 34 may be provided within the liquid recovery member 30, and also an exhaust passage that is connected with a vacuum apparatus including a vacuum pump may be provided in the arm member (41, etc.) of the first transfer system (H1, etc.). Then, when the liquid recovery member 30 is supported by the arm member (41, etc.) of the first transfer system (H1, etc.), the substrate P may be vacuum chucked to the upper surface of the first side plate 34 of the liquid recovery member 30 by connecting the exhaust passage of the liquid recovery member 30 with the exhaust passage of the arm member.

In the projection optical system PL of the aforementioned respective embodiments, the optical path space on the image plane side of the optical element FL at the front end is filled with a liquid, but a projection optical system, as disclosed in PCT International Publication No. WO 2004/019128, in which the optical path space on the object plane side of the optical element FL at the front end is also filled with a liquid, may be adopted.

It is to be noted that as for the substrate P of the aforementioned respective embodiments, not only a semiconductor wafer for manufacturing a semiconductor device, but also a glass substrate for a display device, a ceramic wafer for a thin film magnetic head, or a master mask or reticle (synthetic quartz or silicon wafer), etc. for used in an exposure apparatus can be used. The shape of the substrate is not limited to a circle, and may be another shape such as a rectangle.

As for the exposure apparatus EX, in addition to a scan type exposure apparatus (scanning stepper) in which while synchronously moving the mask M and the substrate P, the pattern of the mask M is scan-exposed, a step-and-repeat type projection exposure apparatus (stepper) in which the pattern of the mask M is exposed at one time in the condition that the mask M and the substrate P are stationary, and the substrate P is successively moved stepwise can be used.

Moreover, as for the exposure apparatus EX, the present invention can be applied to an exposure apparatus of a method in which a reduced image of a first pattern is exposed in a batch on the substrate P by using the projection optical system (for example, a refractive projection optical system having, for example, a reduction magnification of ⅛, which does not include a reflecting element), in the state with the first pattern and the substrate P being substantially stationary. In this case, the present invention can be also applied to a stitch type batch exposure apparatus in which after the reduced image of the first pattern is exposed in a batch, a reduced image of a second pattern is exposed in a batch on the substrate P, partially overlapped on the first pattern by using the projection optical system, in the state with the second pattern and the substrate P being substantially stationary. As the stitch type exposure apparatus, a step-and-stitch type exposure apparatus in which at least two patterns are transferred onto the substrate P in a partially overlapping manner, and the substrate P is sequentially moved can be used.

The types of exposure apparatuses EX are not limited to exposure apparatuses for semiconductor element manufacture that expose a semiconductor element pattern onto a substrate P, but are also widely applicable to exposure apparatuses for the manufacture of liquid crystal display elements and for the manufacture of displays, and exposure apparatuses for the manufacture of thin film magnetic heads, image pickup elements (CCD), micro machines, MEMS, DNA chips, and reticles or masks.

In the aforementioned embodiments, an optical transmission type mask formed with a predetermined shielding pattern (or phase pattern or dimming pattern) on an optical transmission substrate is used. However instead of this mask, for example as disclosed in U.S. Pat. No. 6,778,257, an electronic mask (called a variable form mask; for example this includes a DMD (Digital Micro-mirror Device) as one type of non-radiative type image display element) for forming a transmission pattern or reflection pattern, or a light emitting pattern, based on electronic data of a pattern to be exposed may be used.

Furthermore the present invention can also be applied to an exposure apparatus (lithography system) which exposes a line-and-space pattern on a substrate P by forming interference fringes on the substrate P, as disclosed for example in PCT International Publication No. WO 2001/035168.

Moreover, the present invention can also be applied to an exposure apparatus or the like as disclosed for example in Published Japanese Translation No. 2004-519850 (corresponding to U.S. Pat. No. 6,611,316), which combines patterns of two masks on a substrate via a projection optical system, and double exposes a single shot region on the substrate at substantially the same time, using a single scan exposure light.

As far as is permitted, the disclosures in all of the Japanese Patent Publications and U.S. patents related to exposure apparatuses and the like cited in the above respective embodiments and modified examples, are incorporated herein by reference.

As described above, the exposure apparatus EX is manufactured by assembling various subsystems including the respective constituent elements, so that the prescribed mechanical precision, electrical precision and optical precision can be maintained. To ensure these respective precisions, performed before and after this assembly are adjustments for achieving optical precision with respect to the various optical systems, adjustments for achieving mechanical precision with respect to the various mechanical systems, and adjustments for achieving electrical precision with respect to the various electrical systems. The process of assembly from the various subsystems to the exposure apparatus includes mechanical connections, electrical circuit wiring connections, air pressure circuit piping connections, etc. among the various subsystems. Obviously, before the process of assembly from these various subsystems to the exposure apparatus, there are the processes of individual assembly of the respective subsystems. When the process of assembly to the exposure apparatuses of the various subsystems has ended, overall assembly is performed, and the various precisions are ensured for the exposure apparatus as a whole. Note that it is preferable that the manufacture of the exposure apparatus be performed in a clean room in which the temperature, the degree of cleanliness, etc. are controlled.

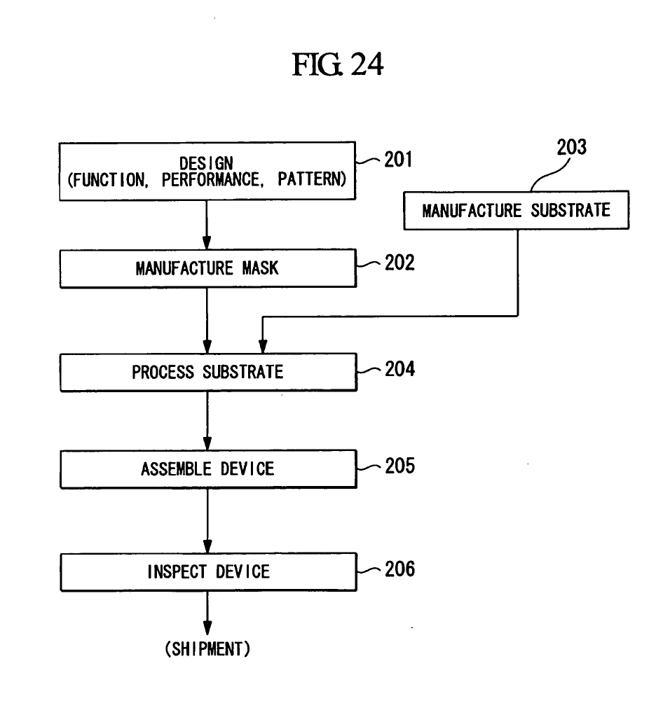

As shown in FIG. 24, microdevices such as semiconductor devices are manufactured by going through: a step 201 that performs microdevice function and performance design; a step 202 that creates the mask (reticle) based on this design step; a step 203 that manufactures the substrate that is the device base material; a substrate processing step 204 including an exposure process for exposing the pattern on the mask onto a substrate by means of the exposure apparatus EX of the aforementioned embodiments, a development process for developing the exposed substrate, and so on; a device assembly step (including a dicing process, a bonding process and a packaging process) 205; and an inspection step 206, and so on.

What is claimed is:

1. A liquid recovery member that is detachably held by a movable member capable of moving with respect to an optical path of an exposure light to be irradiated onto a substrate via a liquid and that comprises an opening portion in which a liquid having flowed out from an upper surface of the substrate flows.

2. The liquid recovery member according to claim 1 further comprising a recess-shaped liquid holding portion that is formed below the opening portion so as to be capable of holding a predetermined amount of the liquid having flowed in via the opening portion.

3. The liquid recovery member according to claim 2, wherein it is held by the movable member so that a part of the opening portion faces a bottom surface of the substrate.

4. The liquid recovery member according to claim 2, wherein it is held by the movable member so that the opening portion surrounds the substrate.

5. The liquid recovery member according to claim 1, wherein it is held by the movable member so that at least a part thereof faces a bottom surface of the substrate.

6. The liquid recovery member according to claim 1, wherein it is held by the removable member so as to surround the substrate.

7. The liquid recovery member according to claim 1, further comprising an absorption member that absorbs the liquid having flowed out from the upper surface of the substrate.

8. The liquid recovery member according to claim 7, wherein the absorption member includes a porous member.

9. The liquid recovery member according to claim 1, further comprising a support portion that supports the substrate.

10. The liquid recovery member according to claim 9, wherein at least either one of at least a part of an attachment operation thereof to the movable member and at least a part of an detachment operation thereof from the movable member is performed in a state with the substrate supported by the support portion.

11. The liquid recovery member according to claim 1, wherein the movable member includes a substrate holding member that detachably holds the substrate.

12. A substrate holding member for holding a substrate to be immersion exposed, comprising:
a first holding portion that detachably holds a substrate; and
a second holding portion that detachably holds a liquid recovery member, the liquid recovery member recovering a liquid having flowed out from an upper surface of the substrate held by the first holding portion.

13. The substrate holding member according to claim 12, wherein the liquid recovery member comprises: an opening portion that is arranged so that the liquid from the upper surface of the substrate flows therein; and a recess-shaped liquid holding portion that is formed below the opening portion so as to be capable of holding a predetermined amount of the liquid having flowed in via the opening portion.

14. The substrate holding member according to claim 13, wherein the second holding portion holds the liquid recovery member so that a part of the opening portion faces a bottom surface of the substrate.

15. The substrate holding member according to claim 13, wherein the second holding portion holds the liquid recovery member so that the opening portion surrounds the substrate.

16. The substrate holding member according to claim 12, wherein the second holding portion holds the liquid recovery member at a position lower than the substrate that is held by the first holding portion.

17. The substrate holding member according to claim 16, wherein the second holding portion holds the liquid recovery member so that at least a part of the liquid recovery member faces the bottom surface of the substrate that is held by the first holding portion.

18. The substrate holding member according to claim 16, wherein the second holding portion holds the liquid recovery member so that the liquid recovery member surrounds the substrate.

19. The substrate holding member according to claim 12, wherein the liquid recovery member comprises an absorption member that absorbs the liquid having flowed out from the upper surface of the substrate.

20. The substrate holding member according to claim 19, wherein the absorption member comprises a porous member.

21. The substrate holding member according to claim 12, wherein
the liquid recovery member comprises a support portion that supports the substrate, and
at least one of a carry-in operation of the substrate to the first holding portion and a carry-out operation of the substrate from the first holding portion is performed in a condition that the substrate is supported by the liquid recovery member.

22. The substrate holding member according to claim 21, wherein the substrate held on the first holding portion and the liquid recovery member held in the second holding portion are apart from each other.

23. An exposure apparatus, comprising:
the substrate holding member according to claim 12, wherein
a liquid immersion exposure for a substrate held by the substrate holding member is performed by irradiating an exposure light onto the substrate via a liquid.

24. The exposure apparatus according to claim 23, further comprising a liquid supply member that is capable of supplying the liquid from above the substrate.

25. The exposure apparatus according to claim 23, further comprising a first transfer device that is capable of transferring the liquid recovery member.

26. The exposure apparatus according to claim 25, wherein the first transfer device is capable of transferring the liquid recovery member while supporting the substrate by means of the liquid recovery member.

27. The exposure apparatus according to claim 26, wherein the first transfer device carries in the substrate together with the liquid recovery member to the substrate holding member and carries out the substrate together with the liquid recovery member from the substrate holding member.

28. The exposure apparatus according to claim 27, wherein the first transfer device transfers the liquid recovery member together with the substrate, passes the substrate from the liquid recovery member to the first holding portion of the substrate holding member, and subsequently passes the liquid recovery member to the second holding portion of the substrate holding member.

29. The exposure apparatus according to claim 27, wherein the first transfer device detaches the liquid recovery member from the second holding portion of the substrate holding member, passes the substrate from the first holding portion of the substrate holding member to the liquid recovery member, and subsequently carries out the liquid recovery member together with the substrate.

30. The exposure apparatus according to claim 26, further comprising
a second transfer device that transfers only the substrate, wherein
the second transfer device transfers the substrate to and from the first transfer device.

31. The exposure apparatus according to claim 25, further comprising
a container apparatus that is capable of containing the liquid recovery member, wherein
the first transfer device is capable of performing a carry-out operation of the liquid recovery member from the container apparatus and/or a carry-in operation of the liquid recovery member to the container apparatus.

32. A device manufacturing method, comprising:
exposing a substrate by using the exposure apparatus according to claim 23; and
developing the substrate that has been exposed.
